(19) United States
(12) Patent Application Publication
(10) Pub. No.: US 2014/0061877 A1
(43) Pub. Date: Mar. 6, 2014

(54) WIRING BOARD WITH EMBEDDED DEVICE, BUILT-IN STOPPER AND ELECTROMAGNETIC SHIELDING

(71) Applicant: Bridge Semiconductor Corporation, Taipei City (TW)

(72) Inventors: Charles W.C. LIN, Singapore (SG); Chia-Chung WANG, Hsinchu (TW); Cheng-Chung CHEN, Taipei City (TW)

(73) Assignee: Bridge Semiconductor Corporation, Taipei City (TW)

(21) Appl. No.: 14/043,933

(22) Filed: Oct. 2, 2013

Related U.S. Application Data
(63) Continuation-in-part of application No. 13/733,226, filed on Jan. 3, 2013.
Application No. 13/733,226 is a continuation-in-part of application No. 13/738,314, filed on Jan. 10, 2013.
Application No. 13/738,314 is a continuation-in-part of application No. 13/753,570, filed on Jan. 30, 2013.
Application No. 13/753,570 is a continuation-in-part of application No. 13/753,589, filed on Jan. 30, 2013.
Application No. 13/753,589 is a continuation-in-part of application No. 13/962,991, filed on Aug. 9, 2013.
Application No. 13/962,991 is a continuation-in-part of application No. 13/969,641, filed on Aug. 19, 2013.
Application No. 13/962,991 is a continuation-in-part of application No. 13/615,819, filed on Sep. 14, 2012.
Application No. 13/615,819 is a continuation-in-part of application No. 13/753,625, filed on Jan. 30, 2013.
Application No. 13/753,625 is a continuation-in-part of application No. 13/733,226, filed on Jan. 3, 2013.
Application No. 13/969,641 is a continuation-in-part of application No. 13/733,226, filed on Jan. 3, 2013.
Application No. 13/733,226 is a continuation-in-part of application No. 13/738,314, filed on Jan. 10, 2013.
Application No. 13/738,314 is a continuation-in-part of application No. 13/753,570, filed on Jan. 30, 2013.
Application No. 13/753,570 is a continuation-in-part of application No. 13/753,589, filed on Jan. 30, 2013.
Application No. 13/753,625 is a continuation-in-part of application No. 13/615,819, filed on Sep. 14, 2012.
Application No. 13/753,570 is a continuation-in-part of application No. 13/733,226, filed on Jan. 3, 2013.
Application No. 13/753,589 is a continuation-in-part of application No. 13/733,226, filed on Jan. 3, 2013.
Application No. 13/753,570 is a continuation-in-part of application No. 13/738,314, filed on Jan. 10, 2013.
Application No. 13/753,589 is a continuation-in-part of application No. 13/738,314, filed on Jan. 10, 2013.
(60) Provisional application No. 61/708,821, filed on Oct. 2, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.
(60) Provisional application No. 61/731,564, filed on Nov. 30, 2012.
(60) Provisional application No. 61/692,725, filed on Aug. 24, 2012.

(51) Int. Cl. H01L 23/552

(52) U.S. Cl. CPC H01L 23/552
USPC 257/659

(57) ABSTRACT

In a preferred embodiment, a wiring board with embedded device, built-in stopper and electromagnetic shielding includes a stopper, a semiconductor device, a stiffener with shielding sidewalls, a first build-up circuitry and a second build-up circuitry with a shielding lid. The first and second build-up circuitries cover the semiconductor device, the stopper and the stiffener in the opposite vertical directions. The shielding sidewalls and the shielding lid are electrically connected to at least one ground contact pad of the semiconductor device by the first build-up circuitry and can respectively serve as effective horizontal and vertical electromagnetic shields for the semiconductor device within the aperture of the stiffener.

### CROSS REFERENCE TO RELATED APPLICATION

This application is a continuation-in-part of U.S. application Ser. No. 13/733,226 filed Jan. 3, 2013, a continuation-in-part of U.S. application Ser. No. 13/738,314 filed Jan. 10, 2013, a continuation-in-part of U.S. application Ser. No. 13/753,570 filed Jan. 30, 2013, a continuation-in-part of U.S. application Ser. No. 13/753,589 filed Jan. 30, 2013, a continuation-in-part of U.S. application Ser. No. 13/962,991 filed Aug. 9, 2013 and a continuation-in-part of U.S. application Ser. No. 13/969,641 filed Aug. 19, 2013, each of which is incorporated by reference. This application also claims the benefit of filing date of U.S. Provisional Application Ser. No. 61/708,821 filed Oct. 2, 2012.

U.S. application Ser. No. 13/962,991 filed Aug. 9, 2013 is a continuation-in-part of U.S. application Ser. No. 13/615,819 filed Sep. 14, 2012, a continuation-in-part of U.S. application Ser. No. 13/753,625 filed Jan. 30, 2013 and a continuation-in-part of U.S. application Ser. No. 13/733,226 filed Jan. 3, 2013. U.S. application Ser. No. 13/969,641 filed Aug. 19, 2013 is a continuation-in-part of U.S. application Ser. No. 13/733,226 filed Jan. 3, 2013, a continuation-in-part of U.S. application Ser. No. 13/738,314 filed Jan. 10, 2013, a continuation-in-part of U.S. application Ser. No. 13/753,570 filed Jan. 30, 2013 and a continuation-in-part of U.S. application Ser. No. 13/753,589 filed Jan. 30, 2013.

U.S. application Ser. No. 13/753,625 filed Jan. 30, 2013 is a continuation-in-part of U.S. application Ser. No. 13/615,819 filed Sep. 14, 2012. U.S. application Ser. No. 13/753,570 filed Jan. 30, 2013 and U.S. application Ser. No. 13/753,589 filed Jan. 30, 2013 are each a continuation-in-part of U.S. application Ser. No. 13/733,226 filed Jan. 3, 2013 and a continuation-in-part of U.S. application Ser. No. 13/738,314 filed Jan. 10, 2013.

U.S. application Ser. No. 13/615,819 filed Sep. 14, 2012, U.S. application Ser. No. 13/753,625 filed Jan. 30, 2013, U.S. application Ser. No. 13/733,226 filed Jan. 3, 2013, U.S. application Ser. No. 13/738,314 filed Jan. 10, 2013, U.S. application Ser. No. 13/753,570 filed Jan. 30, 2013 and U.S. Application Serial No. 13/753,589 filed Jan. 30, 2013 all claim the benefit of filing date of U.S. Provisional Application Ser. No. 61/682,801 filed Aug. 14, 2012. U.S. application Ser. No. 13/962,991 filed Aug. 9, 2013 claims the benefit of filing date of U.S. Provisional Application Ser. No. 61/731,564 filed Nov. 30, 2012. U.S. application Ser. No. 13/969,641 filed Aug. 19, 2013 claims the benefit of filing date of U.S. Provisional Application Ser. No. 61/692,725 filed Aug. 24, 2012.

### BACKGROUND OF THE INVENTION

1. Field of the Invention

The present invention relates to a wiring board with an embedded device, a built-in stopper and electromagnetic shielding, and more particularly to a wiring board having a shielding lid and shielding sidewalls that can respectively serve as vertical and horizontal shields for the embedded device.

2. Description of Related Art

The semiconductor devices are susceptible to electromagnetic interference (EMI) or other inter-device interference, such as capacitive, inductive, conductive coupling when operated in a high frequency mode. These undesirable interferences may become increasingly serious when the semiconductor dies are placed closely together for the miniaturization purpose. In order to minimize the electromagnetic interference, shielding may be required on certain semiconductor devices and modules.

U.S. Pat. No. 8,102,032 to Bolognia et al., U.S. Pat. No. 8,105,872 to Pagaila et al., U.S. Pat. No. 8,093,691 to Fuentes et al., U.S. Pat. No. 8,314,486 and U.S. Pat. No. 8,349,658 to Chi et al. disclose various methods used for shielding of semiconductor devices including metal cans, wire fences, or ball fences. All of the above approaches are designed for the devices assembled on a substrate and the shielding materials such as metal cans, metal film, wire or ball fences are all external added-on which requires additional space and thus increases the footprint of the semiconductor package and the extra cost.

U.S. Pat. No. 7,929,313, U.S. Pat. No. 7,957,154 and U.S. Pat. No. 8,168,893 to Ito et al. disclose a method of using conductive via hole in a resin layer to form an electromagnetic shielding layer that surrounds a concave portion for housing an embedded semiconductor device. This structure promises a superior electrical shielding for the embedded devices at minimal space, but the conductive via which needs to be as deep as the thickness of semiconductor device suffers limitations in high aspect ratio of via drilling and via plating and can only accommodate some ultra-thin devices. Furthermore, as the concave portion which serves as the die placement area is formed after the metallization of conductive via, dislocation of semiconductor device due to poor alignment makes this method prohibitively low yield in volume manufacturing.

### SUMMARY OF THE INVENTION

The present invention has been developed in view of such a situation, and an object thereof is to provide a wiring board in which an embedded device can be affixed at a predetermined location and be shielded from electromagnetic interference. Accordingly, the present invention provides a wiring board that includes a shielding lid, a semiconductor device, a stopper, a stiffener having an aperture with shielding sidewalls, a first build-up circuitry, and optionally a second build-up circuitry. Further, the present invention also provide another wiring board that includes a semiconductor device, a stopper, a stiffener having an aperture with shielding sidewalls, a first build-up circuitry, and a second build-up circuitry with a shielding lid.

In a preferred embodiment, the stopper serves as a placement guide for the semiconductor device. The stopper is in close proximity to and laterally aligned with and laterally extends beyond peripheral edges of the semiconductor device in lateral directions. The semiconductor device and the stopper extend into the aperture of the stiffener. The shielding sidewalls of the aperture laterally cover peripheral edges of the semiconductor device in the lateral directions. The shielding lid covers the semiconductor device in the second vertical direction. The shielding sidewalls and the shielding lid are electrically connected to at least one ground contact pad of the semiconductor device and can respectively serve as lateral and vertical shields for the semiconductor device. The first build-up circuitry and the second build-up circuitry cover the semiconductor device, the stopper and the stiffener from the first and second vertical directions, respectively.

The semiconductor device includes an active surface with a plurality of contact pads thereon and an inactive surface opposite to the active surface. The active surface of the semiconductor device faces the first vertical direction away from the shielding lid, and the inactive surface of the semiconductor device faces the second vertical direction toward the shielding lid. The semiconductor device can be affixed on the first or second build-up circuitry or mounted on the shielding lid by an adhesive.

The stopper can be made of a metal, a photosensitive plastic material or non-photosensitive material. For instance, the stopper can consist essentially of copper, aluminum, nickel, iron, tin or their alloys. The stopper can also consist of epoxy or polyimide.

The stiffener includes an aperture with electrically conductive sidewalls and can be affixed on the shielding lid or an insulating layer of the first build-up circuitry or the second build-up circuitry using the adhesive. The stiffener can extend to peripheral edges of the wiring board and provide mechanical support to suppress warp and bend of the wiring board. The stiffener can be a single or multi-layer structure with embedded single-level conductive traces or multi-level conductive traces, such as multi-layer circuit board. The stiffener can be made of nonmetallic materials, such as various inorganic or organic insulating materials including ceramics, aluminum oxide (Al₂O₃), aluminum nitride (AlN), silicon nitride (SiN), silicon (Si), glass, laminated epoxy, polyimde or copper-clad laminate. By a plating process, the aperture of the nonmetallic stiffener can be formed with metallized sidewalls to provide lateral EMI shields for semiconductor devices within the aperture. Also, the first and second surfaces of the stiffener can be metallized by the plating process, and thus the stiffener includes a conductive layer at the first and second surfaces thereof that is electrically connected to and adjacent to the shielding sidewalls. The stiffener can also be made of metal, such as copper (Cu), aluminum (Al), stainless steel, etc. In order to provide effective lateral EMI shielding, the shielding sidewalls preferably completely cover the lateral surfaces of the semiconductor device to minimize the lateral electromagnetic interference. Further, the shielding sidewalls can be electrically connected to at least one ground contact pad of the semiconductor device by the first build-up circuitry. For instance, the shielding sidewalls can be electrically connected to the first build-up circuitry through conductive vias of the first build-up circuitry in electrical connection with the conductive layer at the first surface of the stiffener. As a result, the electrical connection between the shielding sidewalls and the ground contact pad of the semiconductor device can be provided by the first build-up circuitry. Alternatively, the shielding sidewalls may be electrically connected to the first build-up circuitry by one or more plated through holes that extend through the stiffener. For instance, the plated through hole can extend through the stiffener and be adjacent to the conductive layer of the stiffener, and at a first end can extend to and be electrically connected to the first build-up circuitry. As a result, the electrical connection between the shielding sidewalls and the ground contact pad of the semiconductor device can be provided by the plated through hole and the first build-up circuitry.

The shielding lid is aligned with and covers the semiconductor device from the second vertical direction and can be electrically connected to at least one ground contact pad of the semiconductor device by the first build-up circuitry. The shielding lid can be a continuous metal layer and preferably laterally extends at least to a perimeter coincident with peripheral edges of the semiconductor device in order to provide effective vertical EMI shielding. For instance, the shielding lid can laterally extend to be coplanar with peripheral edges of the semiconductor device in the lateral directions, or laterally extend beyond peripheral edges of the semiconductor device outward and even laterally extend to peripheral edges of the wiring board. Accordingly, the shielding lid that completely covers the semiconductor device from the second vertical direction can minimize the vertical electromagnetic interference. The shielding lid spaced from the first build-up circuitry can be electrically connected to the first build-up circuitry by the stiffener in electrical connection with the first build-up circuitry. For instance, the shielding lid can be electrically connected to the conductive layer at the second surface of the stiffener through conductive vias or conductive trenches that contact and provide electrical connection between the shielding lid and the conductive layer of the stiffener. As a result, the electrical connection between the shielding lid and the ground contact pad of the semiconductor device can be provided by the stiffener and the first build-up circuitry. Also, the shielding lid may be electrically connected to the first build-up circuitry by one or more plated through holes that extend through the stiffener. For instance, the plated through hole at a first end can extend to and be electrically connected to the first build-up circuitry, and at a second end can extend to and electrically connected to the shielding lid. As a result, the electrical connection between the shielding lid and the ground contact pad of the semiconductor device can be provided by the plated through hole and the first build-up circuitry.

The first build-up circuitry covers the stopper, the semiconductor device and the stiffener from the first vertical direction and can include a first insulating layer and one or more first conductive traces. For instance, the first insulating layer covers the stopper, the semiconductor device and the stiffener in the first vertical direction and can extend to peripheral edges of the wiring board, and the first conductive traces extend from the first insulating layer in the first vertical direction. The first insulating layer can include first via openings that are disposed adjacent to the contact pads of the semiconductor device. One or more first conductive traces extend from the first insulating layer in the first vertical direction and extend laterally on the first insulating layer and extend into the first via openings in the second vertical direction to form first conductive vias, thereby providing signal routing for signal contact pads of the semiconductor device and ground connection for ground contact pads of the semiconductor device. Further, the first insulating layer can include one or more additional first via openings that are disposed adjacent to selected portions of the conductive layer at the first surface of the stiffener. The first conductive traces can further extend into the additional first via openings in the second vertical direction to form one or more additional first conductive vias in electrical contact with the conductive layer of the stiffener, thereby providing ground connection between ground contact pads of semiconductor device and the shielding sidewalls. In summary, the first build-up circuitry is electrically connected to the contact pads of the semiconductor device through the first conductive vias to provide signal routing and ground connection for the semiconductor device, and can be further electrically connected to the shielding sidewalls through the additional first conductive vias to provide the ground connection for the shielding sidewalls. As the first conductive traces can directly contact the contact pads of the semiconductor device and the conductive layer of the stiffener, the electrical connection between the semiconductor device and the first build-up circuitry and between the shielding sidewalls and the first build-up circuitry can be devoid of solder. The first build-up circuitry can include additional layers of dielectric, additional layers of via openings, and additional layers of conductive traces if needed for further signal routing.

The second build-up circuitry can be optionally provided and cover the shielding lid and the stiffener from the second vertical direction in accordance with one aspect of the wiring board with the semiconductor device mounted on the shielding lid. In this aspect, the second build-up circuitry can include a second insulating layer and one or more second conductive traces. For instance, the second insulating layer covers the shielding lid and the stiffener from the second vertical direction and can extend to peripheral edges of the wiring board, and the second conductive traces extend from the second insulating layer in the second vertical direction and extend laterally on the second insulating layer. The second insulating layer can include one or more second via openings that are disposed adjacent to selected portions of the shielding lid. The second conductive traces can further extend into the second via openings in the first vertical direction to form one or more second conductive vias, thereby providing electrical connection for the shielding lid. As for another aspect of the wiring board with the shielding lid built in the second build-up circuitry, the second build-up circuitry covers the stopper, the semiconductor device and the stiffener from the second vertical direction and can include a second insulating layer, the shielding lid and optionally second conductive traces. For instance, the second insulating layer covers the stopper, the semiconductor device and the stiffener from the second vertical direction and can extend to peripheral edges of the wiring board, and the shielding lid and the second conductive traces extend from the second insulating layer in the second vertical direction and laterally extend on the second insulating layer. The second insulating layer can include one or more second via openings or trench openings that are disposed adjacent to selected portions of the conductive layer at the second surface of the stiffener and can be metallized to form one or more second conductive vias or conductive trenches. Accordingly, the shielding lid can be electrically connected to the first build-up circuitry for ground connection through the stiffener and the second conductive via or the conductive trench of the second build-up circuitry. The second build-up circuitry can include additional layers of dielectric, additional layers of via openings, and additional layers of conductive traces if needed for further signal routing.

The wiring board of the present invention can further include one or more plated through holes that extend through the stiffener. The plated through hole can provide an electrical connection between the first build-up circuitry and the second build-up circuitry. For instance, the plated through hole at a first end can extend to and be electrically connected to an outer or inner conductive layer of the first build-up circuitry, and at a second end can extend to and be electrically connected to an outer or inner conductive layer or the shielding lid of the second build-up circuitry. As a result, the plated through hole can provide electrical connection in vertical directions for signal routing or ground connection.

The outmost conductive traces of the first and second build-up circuitries can respectively include one or more first and second interconnect pads to provide electrical contacts for an electronic device such as a semiconductor chip, a plastic package or another semiconductor assembly. The first interconnect pads can include an exposed contact surface that faces in the first vertical direction, while the second interconnect pads can include an exposed contact surface that faces in the second vertical direction. As a result, the wiring board can include electrical contacts (i.e. the first and second interconnect pads) that are electrically connected to one another and located on opposite surfaces that face in opposite vertical directions, so that the wiring board is stackable and electronic devices can be electrically connected to the wiring board using a wide variety of connection media including wire bonding or solder bumps as the electrical contacts.

The wiring board of the present invention can further include a placement guide for the stiffener. The placement guide for the stiffener can be in close proximity to and laterally aligned with and laterally extend beyond the outer peripheral edges of the stiffener in lateral directions. Like the stopper, the placement guide for the stiffener can be made of a metal, a photosesitive plastic material or non-photosensitive material, such as copper, aluminum, nickel, iron, tin, alloys, epoxy or polyimide.

The stopper and the placement guide can contact and extend from the shielding lid or an insulating layer of the second build-up circuitry in the first vertical direction, or extend from an insulating layer of the first build-up circuitry in the second vertical direction. For instance, the stopper may extend from an insulating layer of the second build-up circuitry or the shielding lid and extend beyond the inactive surface of the semiconductor device in the first vertical direction, or extend from an insulating layer of the first build-up circuitry and extend beyond the active surface of the semiconductor device in the second vertical direction. Likewise, the placement guide may extend from an insulating layer of the second build-up circuitry or the shielding lid and extend beyond the attached surface of the stiffener in the first vertical direction, or extend from an insulating layer of the first build-up circuitry and extend beyond the attached surface of the stiffener in the second vertical direction. In any case, the stopper and the placement guide can contact and be sandwiched between the first build-up circuitry and the second build-up circuitry or between the first build-up circuitry and the shielding lid.

Further, the stopper and the placement guide can have patterns against undesirable movement of the semiconductor device and the stiffener, respectively. For instance, the stopper and the placement guide can include a continuous or discontinuous strip or an array of posts. The stopper and the placement guide can be simultaneously formed and have the same or different patterns. Specifically, the stopper can be laterally aligned with four lateral surfaces of the semiconductor device to stop the lateral displacement of the semiconductor device. For instance, the stopper can be aligned along and conform to four sides, two diagonal corners or four corners of the semiconductor device, and a gap in between the semiconductor device and the stopper preferably is in a range of about 0.001 to 1 mm. The semiconductor device can be spaced from the inner wall of the aperture by the stopper, and a bonding material can be added between the semiconductor device and the stiffener to enhance rigidity. Moreover, the stopper can also be in close proximity to and laterally aligned with the inner wall of the aperture to stop the lateral displacement of the stiffener. Likewise, the placement guide can be laterally aligned with four outer lateral surfaces of the stiffener to stop the lateral displacement of the stiffener. For instance, the placement guide can be aligned along and conform to four outer sides, two outer diagonal corners or four outer corners of the stiffener and a gap in between the outer peripheral edges of the stiffener and the placement guide preferably is in a range of about 0.001 to 1 mm. Besides, the stopper and the placement guide preferably have a thickness in a range of 10-200 microns.

The present invention also provides a three-dimensional stacking module in which plural wiring boards each with embedded device, built-in stopper and electromagnetic shielding are stacked in back-to-back or face-to-back manner using interlayer dielectric between each two neighboring wiring boards and are electrically connected to one another through one or more plated through holes.

The present invention has numerous advantages. The stiffener can provide a mechanical support for the build-up circuitry. The shielding sidewalls of the stiffener and the shielding lid can respectively serve as horizontal and vertical EMI shields for semiconductor device to minimize electromagnetic interference. The electrical connection between ground contact pads of the semiconductor device and the shielding sidewalls/shielding lid can be provided by the build-up circuitry to provide effective electromagnetic shielding effect for the semiconductor device embedded in the wiring board. The signal routing can be provided by the build-up circuitry and is advantageous for high I/O and high performance applications due to the high routing capability of the build-up circuitry. Further, the placement location of the semiconductor device can be accurately confined by the stopper to avoid the electrical connection failure between the semiconductor device and the build-up circuitry resulted from the lateral displacement of the semiconductor device, thereby improving the manufacturing yield greatly. The wiring board and the stacking module using the same are reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1-8 are cross-sectional views showing a method of making a wiring board that includes a stopper, a semiconductor device, a stiffener, dual build-up circuitries and plated through hole in accordance with an embodiment of the present invention, in which FIGS. 2A, 2A′, 3A and 5A are top perspective views corresponding to FIGS. 2, 2′, 3 and 5, FIGS. 2B-2E are top perspective views of other various patterns of the stopper for reference;

FIGS. 9-12 are cross-sectional views showing a method of making another wiring board that includes a shielding lid and shielding sidewalls in electrical connection with ground contact pads of a semiconductor device through conductive vias in accordance with another embodiment of the present invention;

FIGS. 13-15 are cross-sectional views showing a method of making yet another wiring board that includes a shielding lid in electrical connection with a patterned conductive layer of a stiffener through conductive trenches in accordance with yet another embodiment of the present invention, in which FIG. 14A is a bottom perspective view corresponding to FIG. 14;

FIGS. 16-21 are cross-sectional views showing a method of making further another wiring board in which dual build-up circuitries include additional insulating layers and conductive traces and are electrically connected to one another by plated through holes in accordance with further another embodiment of the present invention;

FIGS. 22-28 are cross-sectional views showing another method of making a wiring board that includes a stopper, a shielding lid, a semiconductor device, a stiffener, a build-up circuitry, conductive trenches, terminals and plated through holes in accordance with an embodiment of the present invention;

FIGS. 29-34 are cross-sectional views showing a method of making another wiring board that includes a stopper, a shielding lid, a semiconductor device, a stiffener, dual build-up circuitries and plated through holes in accordance with another embodiment of the present invention;

FIGS. 35-42 are cross-sectional views showing a method of making yet another wiring board with the shielding lid inserted into the aperture of the stiffener in accordance with yet another embodiment of the present invention;

FIGS. 43-45 are cross-sectional views showing a method of making a three-dimensional stacking module that includes plural wiring boards in face-to-back stacking in accordance with one embodiment of the present invention; and

FIGS. 46-48 are cross-sectional views showing a method of making another three-dimensional stacking module that includes plural wiring boards in back-to-back stacking in accordance with another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

FIGS. 1-8 are cross-sectional views showing a method of making a wiring board that includes a stopper, a semiconductor device, a stiffener, dual build-up circuitries and plated through hole in accordance with an embodiment of the present invention.

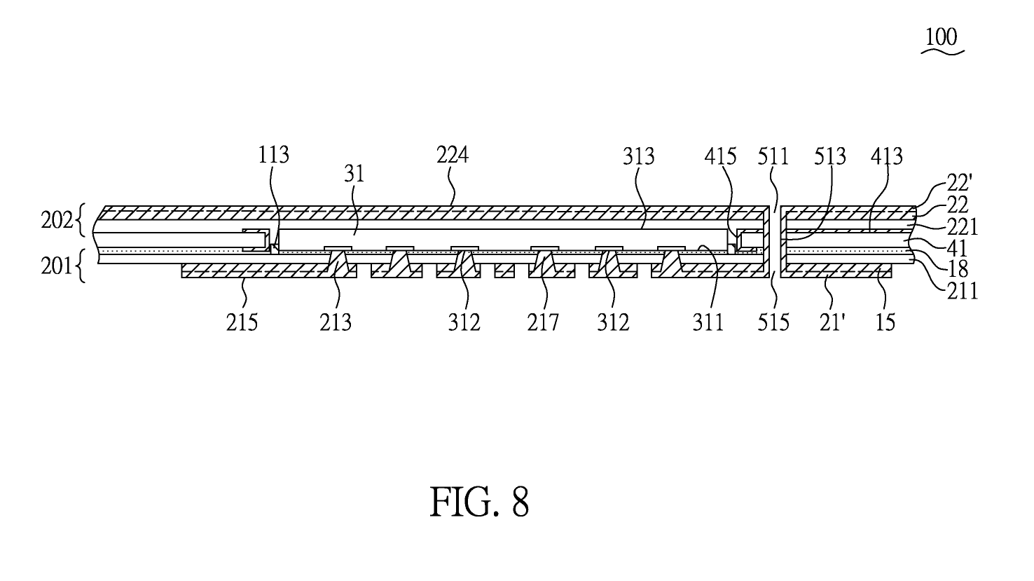

As shown in FIG. 8, wiring board 100 includes stopper 113, semiconductor device 31, stiffener 41, first build-up circuitry 201, second build-up circuitry 202, and plated through hole 515. Semiconductor device 31 includes active surface 311, inactive surface 313 opposite to active surface 311, and contact pads 312 at active surface 311. First build-up circuitry 201 includes first insulating layer 211 and first conductive traces 215 and is electrically connected to semiconductor device 31 through first conductive vias 217. Second build-up circuitry 202 includes second insulating layer 221 and shielding lid 224. Stopper 113 extends from first insulating layer 211 of first build-up circuitry 201 in the upward direction and is in close proximity to peripheral edges of semiconductor device 31. Shielding lid 224 of second build-up circuitry 202 laterally extends on second insulating layer 221 and covers semiconductor device 31 in the upward direction. Shielding sidewalls 415 of stiffener 41 laterally cover semiconductor device 31 in the lateral direction. Plated through hole 515 provides electrical connection between shielding lid 224 and ground contact pad of semiconductor device 31 and between shielding sidewalls 415 and ground contact pad of semiconductor device 31.

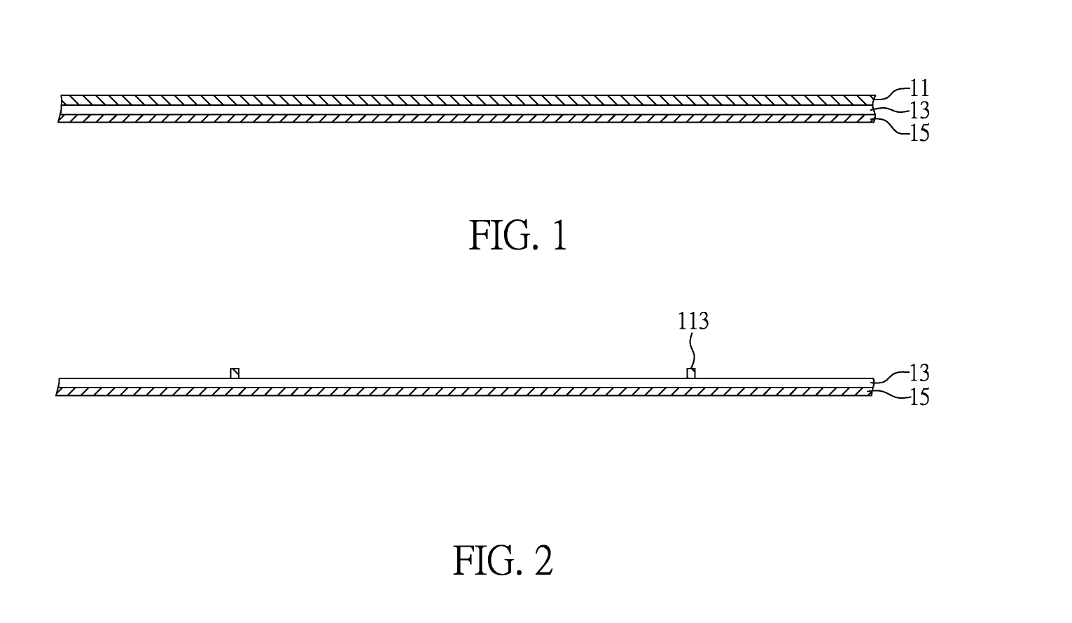

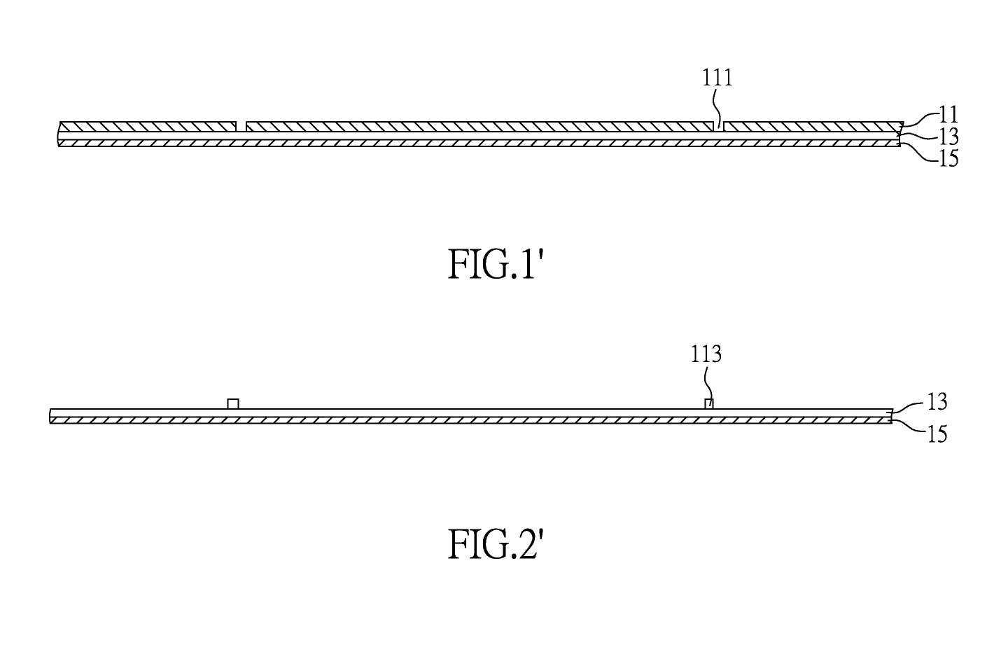

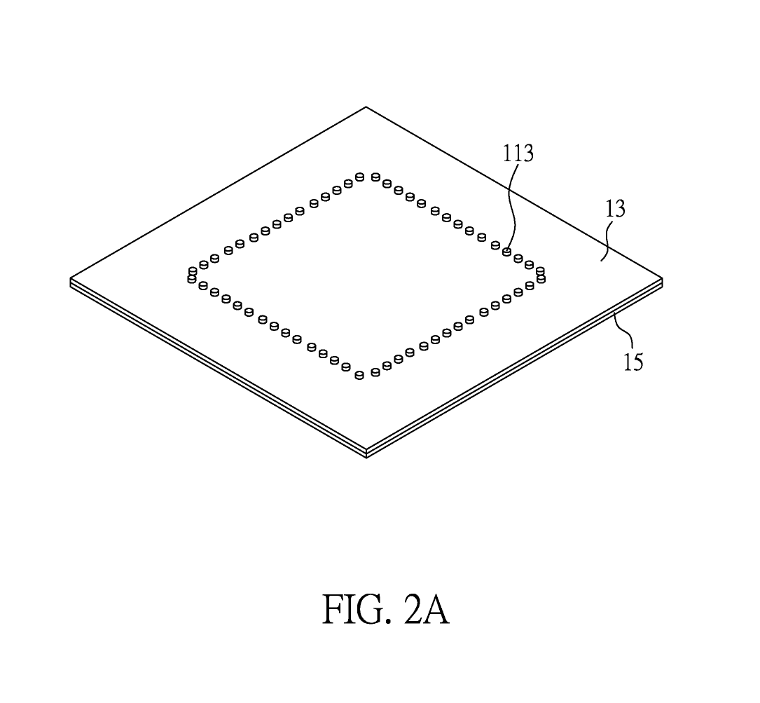

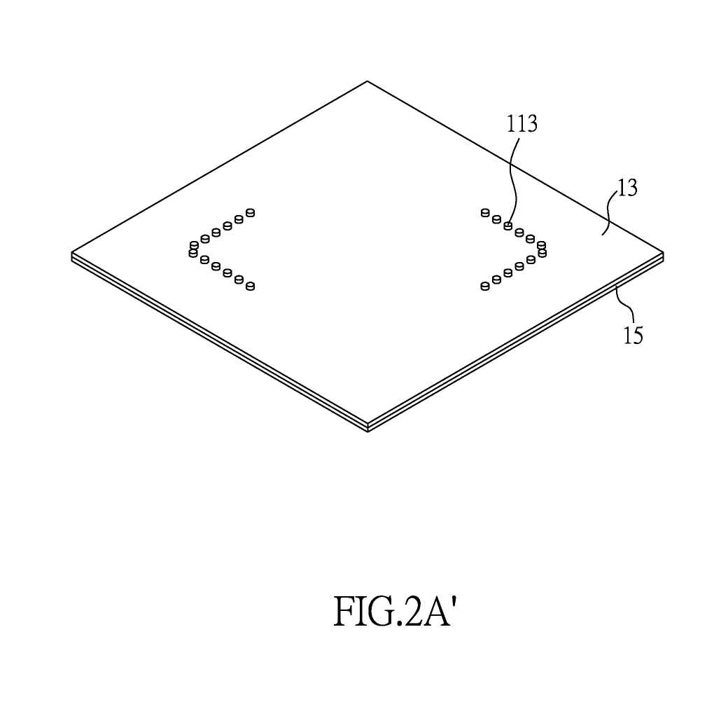

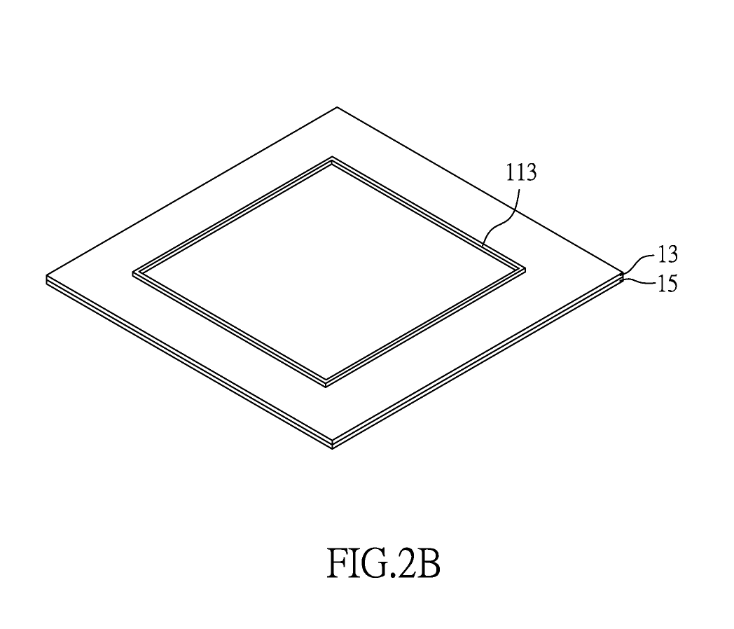

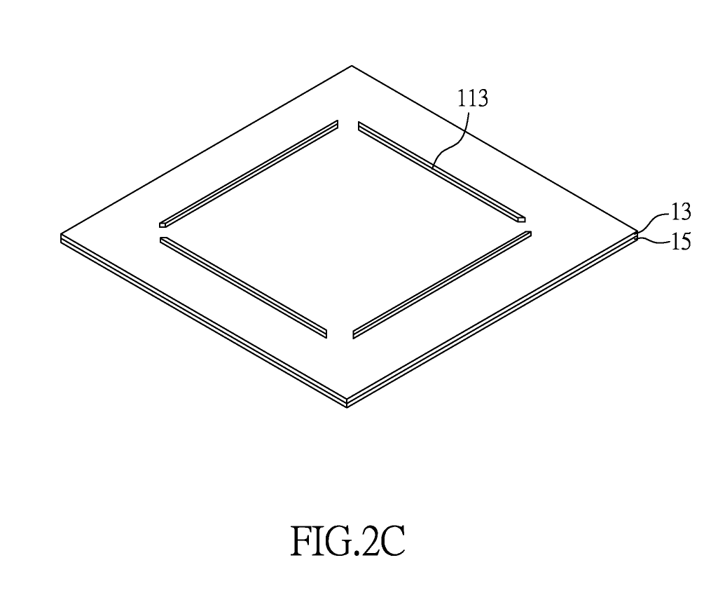

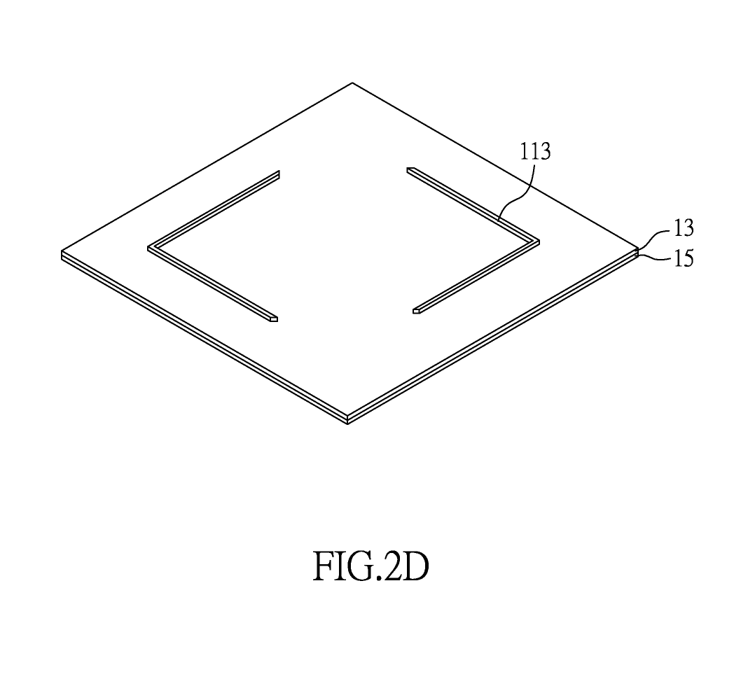

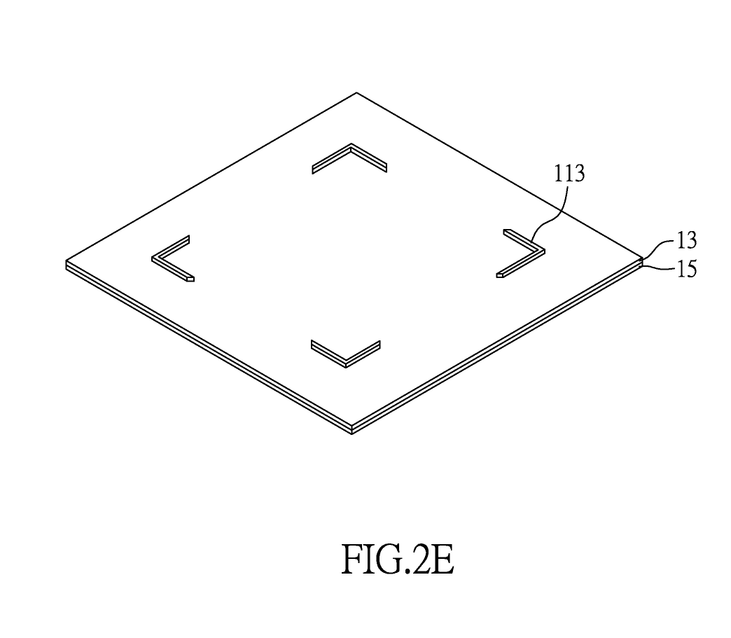

FIGS. 1 and 2 are cross-sectional views showing a method of forming a stopper on a dielectric layer in accordance with an embodiment of the present invention, and FIG. 2A is a top perspective view corresponding to FIG. 2.

FIG. 1 is a cross-sectional view of a laminate substrate that includes metal layer 11, dielectric layer 13 and support plate 15. Metal layer 11 is illustrated as a copper layer with a thickness of 35 microns. However, metal layer 11 can also be made of other various metal materials and is not limited to a copper layer. Besides, metal layer 11 can be deposited on dielectric layer 13 by numerous techniques including lamination, electroplating, electroless plating, evaporating, sputtering, and their combinations as a single layer or multiple layers, and preferably has a thickness in a range of 10 to 200 microns.

Dielectric layer 13 typically is made of epoxy resin, glass-epoxy, polyimide and the like and has a thickness of 50 microns. In this embodiment, dielectric layer 13 is sandwiched between metal layer 11 and support plate 15. However, support plate 15 may be omitted in some embodiments. Support plate 15 typically is made of copper, but copper alloys or other materials are also doable. The thickness of support plate 15 can range from 25 to 1000 microns, and preferably ranges from 35 to 100 microns in consideration of process and cost. In this embodiment, support plate 15 is illustrated as a copper plate with a thickness of 35 microns.

FIGS. 2 and 2A are cross-sectional and top perspective views, respectively, of the structure with stopper 113 formed on dielectric layer 13. Stopper 113 can be formed by removing selected portions of metal layer 11 using photolithography and wet etching. In this illustration, stopper 113 consists of plural metal posts in a rectangular frame array and conforms to four sides of a semiconductor device subsequently disposed on dielectric layer 13. However, stopper patterns are not limited thereto and can be other various patterns against undesirable movement of the subsequently disposed semiconductor device.

FIGS. 1′ and 2′ are cross-sectional views showing an alternative method of forming a stopper on a dielectric layer, and FIG. 2A′is a top perspective view corresponding to FIG. 2′.

FIG. 1′ is a cross-sectional view of a laminate substrate with a set of cavities 111. The laminate substrate includes metal layer 11, dielectric layer 13 and support plate 15 as above mentioned, and cavities 111 are formed by removing selected portions of metal layer 11.

FIGS. 2′ and 2A′ are cross-sectional and top perspective views, respectively, of the structure with stopper 113 formed on dielectric layer 13. Stopper 113 can be formed by dispensing or printing a photosensitive plastic material (e.g., epoxy, polyimide, etc.) or non-photosensitive material into cavities 111, followed by removing overall metal layer 11. Herein, stopper 113 is illustrated as an array of plural resin posts and conforms to two diagonal corners of a subsequently disposed semiconductor device.

FIGS. 2B-2E are top perspective views of other various stopper patterns for reference. For instance, stopper 113 may consist of a continuous or discontinuous strip and conform to four sides (as shown FIGS. 2B and 2C), two diagonal corners or four corners (as shown in FIGS. 2D and 2E) of a subsequently disposed semiconductor device.

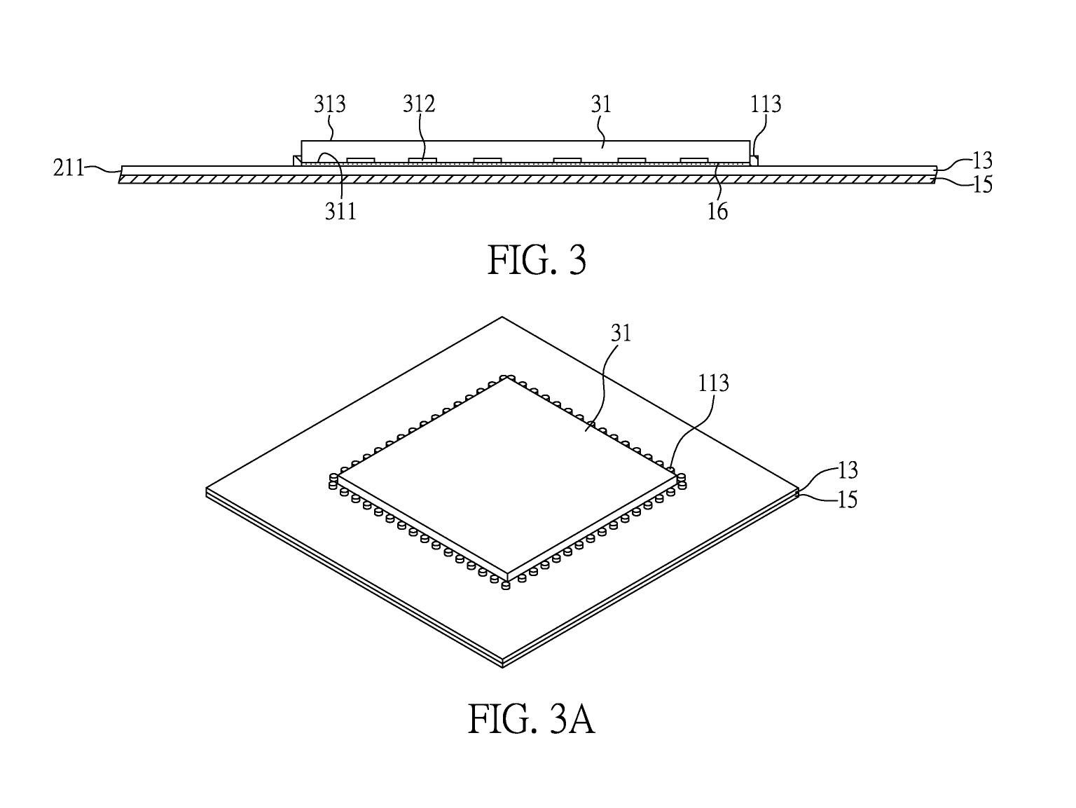

FIGS. 3 and 3A are cross-sectional and top perspective views, respectively, of the structure with semiconductor device 31 mounted on dielectric layer 13 using adhesive 16. Semiconductor device 31 includes active surface 311, inactive surface 313 opposite to active surface 311, and plural contact pads 312 at active surface 311. Semiconductor device 31 is mounted onto dielectric layer 13 with active surface 311 facing dielectric layer 13 that is considered first insulating layer 211 of first build-up circuitry.

Stopper 113 can serve as a placement guide for semiconductor device 31, and thus semiconductor device 31 is precisely placed at a predetermined location. Stopper 113 extends from dielectric layer 13 beyond active surface 311 of semiconductor device 31 in the upward direction and is laterally aligned with and laterally extends beyond four sides of semiconductor device 31 in the lateral directions. As stopper 113 is in close proximity to and conforms to four lateral surfaces of semiconductor device 31 in lateral directions and adhesive 16 under semiconductor device 31 is lower than stopper 113, any undesirable movement of semiconductor device 31 due to adhesive curing can be avoided. Preferably, a gap in between semiconductor device 31 and stopper 113 is in a range of about 0.001 to 1 mm.

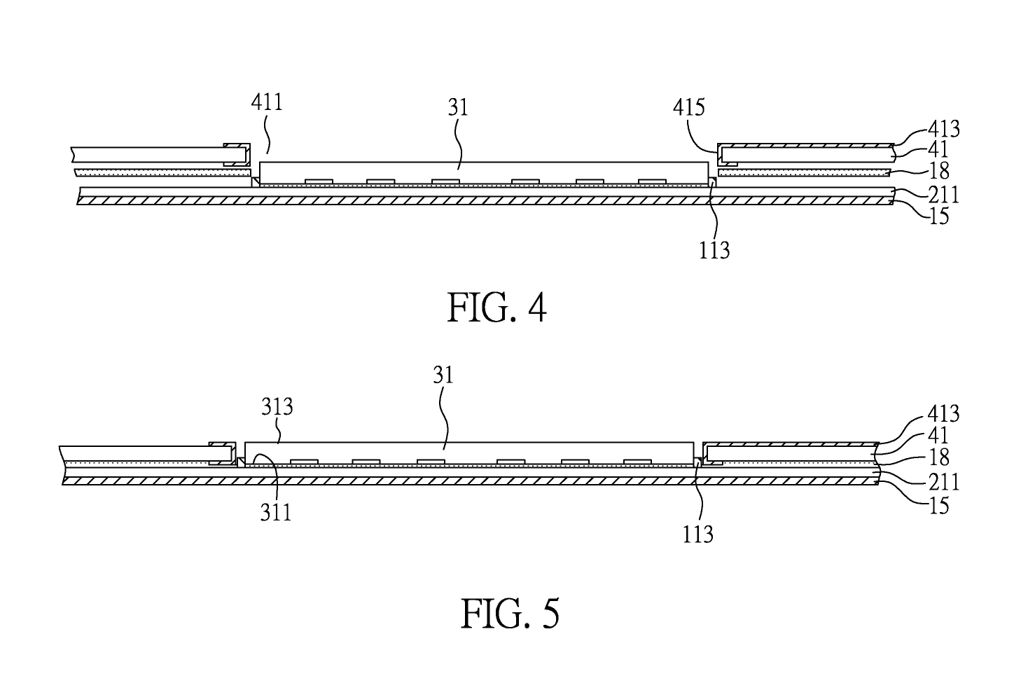

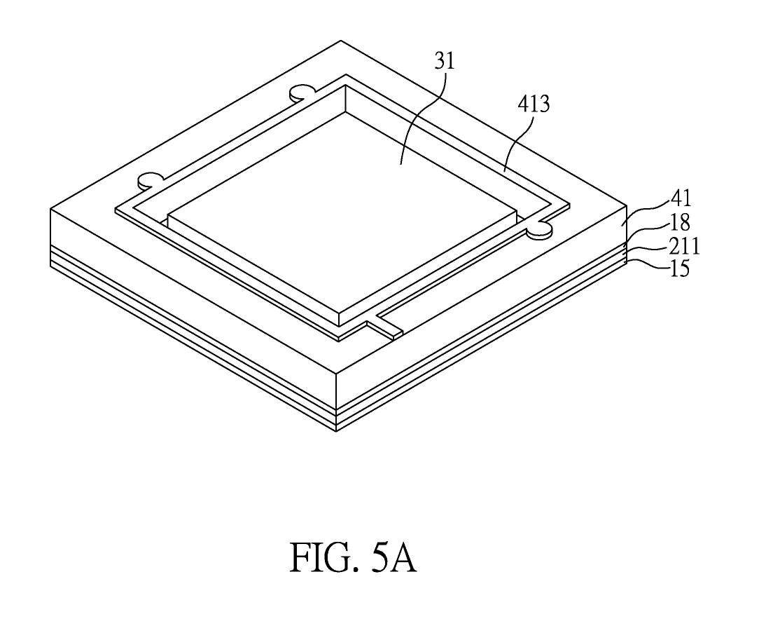

FIGS. 4 and 5 are cross-sectional views showing a process of laminating stiffener 41 onto first insulating layer 211, and FIG. 5A is a top perspective view corresponding to FIG. 5. Semiconductor device 31 and stopper 113 are aligned with aperture 411 of stiffener 41, and stiffener 41 is mounted on first insulating layer 211 using adhesive 18 that contacts and is sandwiched between stiffener 41 and first insulating layer 211. Stiffener 41 is illustrated as a ceramic sheet with conductive layer 413 in aperture 411 as well as on top and bottom surfaces. Aperture 411 is formed by laser cutting through stiffener 41 and can be formed with other techniques such as punching and mechanical drilling. Aperture 411 as well as top and bottom surfaces of stiffener 41 are metallized by plating to provide conductive layer 413 thereon, followed by metal patterning process of conductive layer 413 on top and bottom surfaces. Accordingly, aperture 411 has shielding sidewalls 415 and can provide lateral EMI shielding effect for semiconductor device 31 within aperture 411. In order to provide effective lateral EMI shielding, shielding sidewalls 415 of aperture 411 preferably extend upward at least to a perimeter coincident with inactive surface 313 of semiconductor device 31, and extend downward at least to a perimeter coincident with active surface 311 of semiconductor device 31. In this illustration, stiffener 41 is coplanar with semiconductor device 31 in the upward and downward directions, and shielding sidewalls 415 of aperture 411 laterally cover the lateral surfaces of semiconductor device 31.

Semiconductor device 31 and shielding sidewalls 415 of aperture 411 are spaced from one another by stopper 113. Stopper 113 is also in close proximity to and laterally aligned with four shielding sidewalls 415 of aperture 411 and adhesive 18 under stiffener 41 is lower than stopper 113, and thus any undesirable movement of stiffener 41 also can be avoided before adhesive 18 is fully cured. Optionally, a bonding material (not shown in the figure) can be added between semiconductor device 31 and stiffener 41 to enhance rigidity.

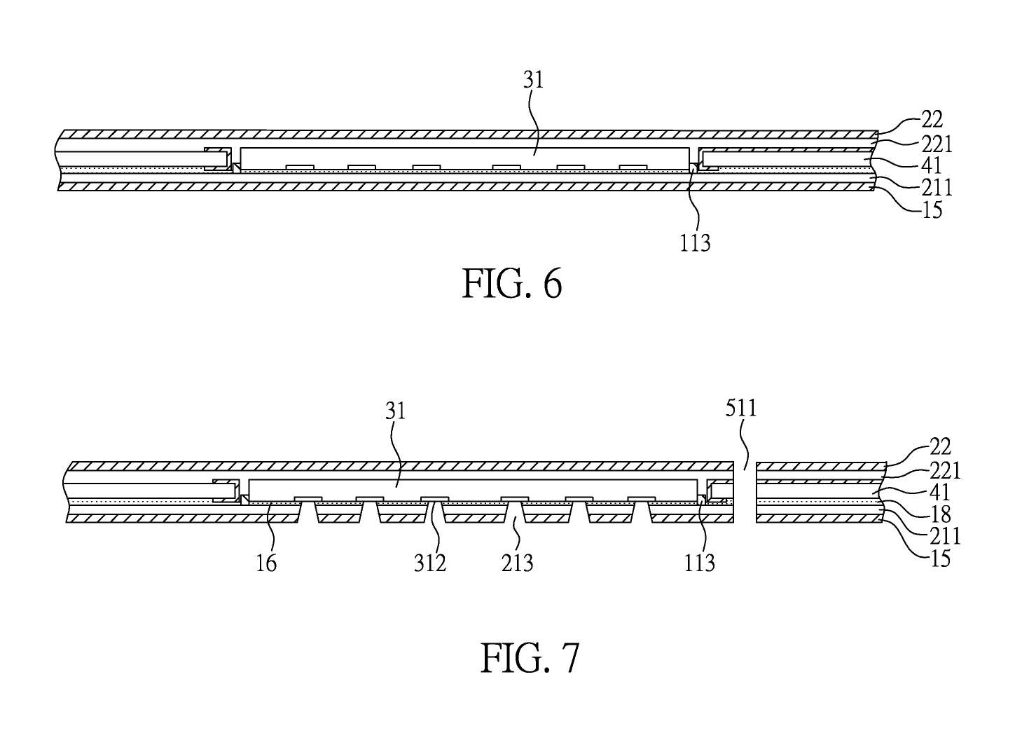

FIG. 6 is a cross-sectional view of the structure laminated with second insulating layer 221 and metal layer 22 onto semiconductor device 31 and stiffener 41 in the upward direction. Second insulating layer 221 is sandwiched between metal layer 22 and semiconductor device 31 and between metal layer 22 and stiffener 41. Second insulating layer 221 can be epoxy resin, glass-epoxy, polyimide and the like and typically has a thickness of 50 microns. Preferably, first insulating layer 211 and second insulating layer 221 are the same material. Metal layer 22 is illustrated as a copper layer with a thickness of 17 microns. Under pressure and heat, second insulating layer 221 is melt and compressed and further extends into the gap between semiconductor device 31 and stiffener 41 in aperture 411 by applying downward pressure to metal layer 22 or/and upward pressure to support plate 15. After second insulating layer 211 and metal layer 22 are laminated onto semiconductor device 31 and stiffener 41, second insulating layer 221 is solidified. Accordingly, as shown in FIG. 6, second insulating layer 221 as solidified provides secure robust mechanical bonds between metal layer 22 and stopper 113, between metal layer 22 and semiconductor device 31, and between metal layer 22 and stiffener 41.

FIG. 7 is a cross-sectional view of the structure provided with first via openings 213 and through hole 511. First via openings 213 extend through support plate 15, first insulating layer 211 and adhesive 16 to expose contact pads 312 of semiconductor device 31 in the downward direction. First via openings 213 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser. Through hole 511 extends through support plate 15, first insulating layer 211, adhesive 18, stiffener 41, second insulating layer 221 and metal layer 22 in the vertical direction. Through hole 511 is formed by mechanical drilling and can be formed by other techniques such as laser drilling and plasma etching with or without wet etching.

Referring now to FIG. 8, first conductive traces 215 are formed on first insulating layer 211 by depositing first plated layer 21′ on support plate 15 and into first via openings 213 and then patterning support plate 15 and first plated layer 21′ thereon. Alternatively, in some embodiments which apply a laminate substrate without support plate 15, first insulating layer 211 can be directly metallized to form first conductive traces 215. First conductive traces 215 extend from first insulating layer 211 in the downward direction, extend laterally on first insulating layer 211 and extend into first via openings 213 in the upward direction to form first conductive vias 217 in direct contact with contact pads 312.

Also shown in FIG. 8 is shielding lid 224 in electrical connection with first conductive traces 215 and patterned conductive layer 413 of stiffener 41 by depositing second plated layer 22′ on metal layer 22 and connecting layer 513 in through hole 511 to provide plated through hole 515 in electrical contact with shieling lid 224, patterned conductive layer 413 and first conductive traces 215. Likewise, second insulating layer 221 also can be directly metallized to form shielding lid 224 when no metal layer 22 is laminated on second insulating layer 221 in the previous process. Shielding lid 224 extends from second insulating layer 221 in the upward direction and laterally extends on second insulating layer 221. In this illustration, shielding lid 224 is a continuous metal layer and laterally extends to the peripheral edges of the wiring board. Further, connecting layer 513 is illustrated as a hollow tube that covers the sidewall of through hole 511 in lateral directions and extends vertically to electrically connect shielding lid 224 and patterned conductive layer 413 of stiffener 41 to first conductive traces 215, and an insulative filler can optionally fill the remaining space in through hole 511. Alternatively, connecting layer 513 can fill through hole 511 in which case plated through hole 515 is a metal post and there is no space for an insulative filler in through hole 511. As a result, shielding lid 224 can be electrically connected to ground contact pad of semiconductor device 31 by first conductive traces 215 and plated through hole 515. Also, shielding sidewalls 415 of stiffener 41 can be electrically connected to ground contact pad of semiconductor device 31 by first conductive traces 215, plated through hole 515 and patterned conductive layer 413.

Preferably, first plated layer 21′, second plated layer 22′ and connecting layer 513 are the same material deposited simultaneously in the same manner and have the same thickness. First plated layer 21′, second plated layer 22′ and connecting layer 513 can be deposited by numerous techniques including electroplating, electroless plating, evaporating, sputtering, and their combinations as a single layer or multiple layers. For instance, they are deposited by first dipping the structure in an activator solution to render the structure catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form first conductive traces 215 by numerous techniques including wet etching, electro-chemical etching, laser-assist etching, and their combinations with an etch mask (not shown) thereon that defines first conductive traces 215.

Support plate 15, first plated layer 21′, metal layer 22, second plated layer 22′ and connecting layer 513 are shown as a single layer for convenience of illustration. The boundary (shown in phantom) between the metal layers may be difficult or impossible to detect since copper is plated on copper. However, the boundaries between first plated layer 21′ and first insulating layer 211, between connecting layer 513 and first insulating layer 211, between connecting layer 513 and adhesive 18, between connecting layer 513 and stiffener 41, and between connecting layer 513 and second insulating layer 221 are clear.

Accordingly, as shown in FIG. 8, wiring board 100 is accomplished and includes stopper 113, semiconductor device 31, stiffener 41, dual build-up circuitries 201, 202 and plated through hole 515. In this illustration, first build-up circuitry 201 includes first insulating layer 211 and first conductive traces 215, while second build-up circuitry 202 includes second insulating layer 221 and shielding lid 224. First conductive traces 215 extend into first via openings 213 in the upward direction to form first conductive vias 217 in direct contact with contact pads 312. Shielding lid 224 laterally extends on second insulating layer 221 and completely covers semiconductor device 31 in the upward direction. Shielding sidewalls 415 laterally enclose and completely cover semiconductor device 31 in the lateral directions. Plated through hole 515 is essentially shared by stiffener 41 and dual build-up circuitries 201, 202, and extend through first insulating layer 211, adhesive 18, stiffener 41 and second insulating layer 221 in the vertical directions to provide electrical connection between shielding lid 224 and first conductive traces 215 and between shielding sidewalls 415 and first conductive traces 215. As a result, shielding sidewalls 415 and shielding lid 224 can be electrically connected to ground contact pads of semiconductor device 31 through first build-up circuitry 201 and plated through hole 515, and serve as horizontal and vertical EMI shields for semiconductor device 31.

### Embodiment 2

FIGS. 9-12 are cross-sectional views showing a method of making another wiring board that includes a shielding lid and shielding sidewalls in electrical connection with ground contact pads of a semiconductor device through conductive vias in accordance with another embodiment of the present invention.

For purposes of brevity, any description in above Embodiment is incorporated herein insofar as the same is applicable, and the same description need not be repeated.

FIG. 9 is a cross-sectional view of the structure which is manufactured by the same steps shown in FIGS. 1-5, except that semiconductor device 31 is mounted on dielectric layer 13 with its inactive surface 313 facing dielectric layer 13, and stopper 113 extends beyond inactive surface 313 of semiconductor device 31 in the upward direction.

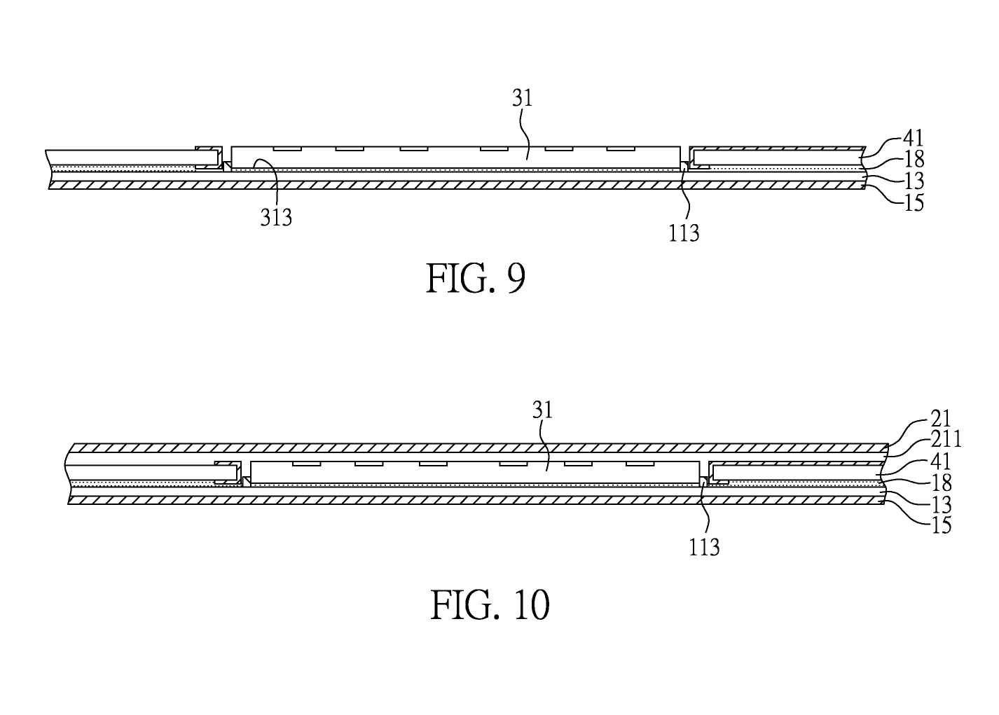

FIG. 10 is a cross-sectional view of the structure laminated with first insulating layer 211 and metal layer 21 onto semiconductor device 31 and stiffener 41 in the upward direction. First insulating layer 211 is melt and compressed and further extends into the gap between semiconductor device 31 and stiffener 41 under pressure and heat, and then solidified to provide robust mechanical bonds between metal layer 21 and semiconductor device 31, between metal layer 21 and stopper 113 and between metal layer 21 and stiffener 41.

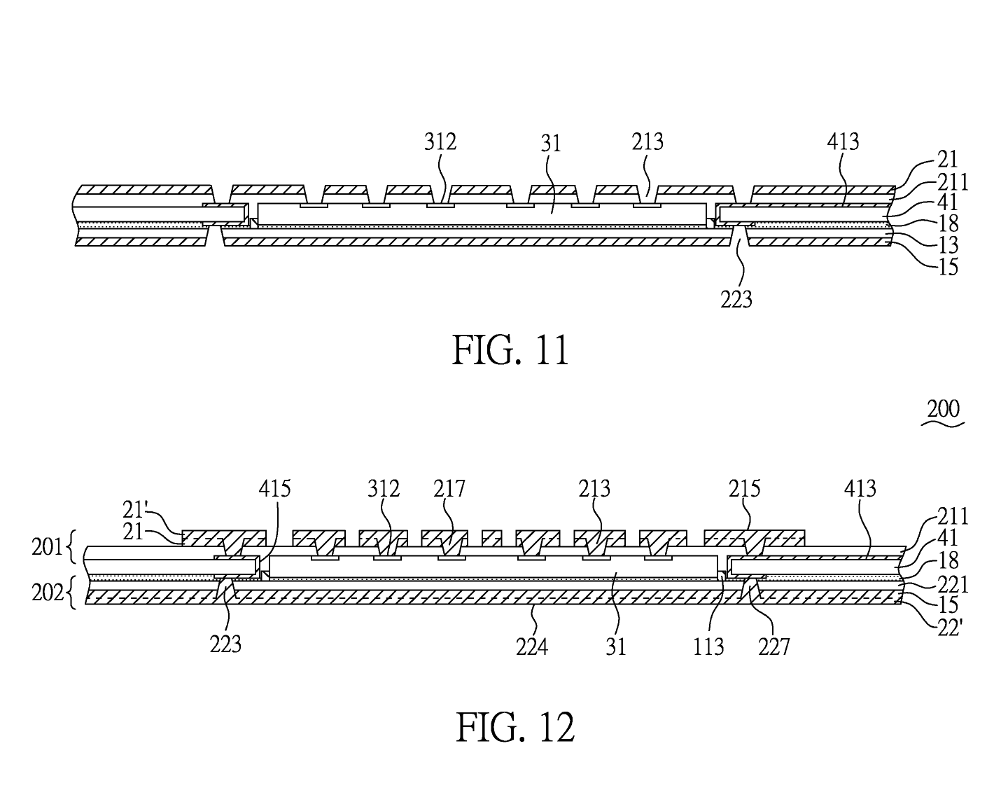

FIG. 11 is a cross-sectional view of the structure provided with first via openings 213 and second via openings 223. First via openings 213 extend through metal layer 21 and first insulating layer 211 to expose contact pads 312 of semiconductor device 31 and selected portions of patterned conductive layer 413 on the top surface of stiffener 41 in the upward direction. Second via openings 223 extend through support plate 15, dielectric layer 13 and adhesive 18 to expose selected portions of patterned conductive layer 413 on the bottom surface of stiffener 41 in the downward direction.

Referring now to FIG. 12, first conductive traces 215 are formed on first insulating layer 211 by depositing first plated layer 21′ on metal layer 21 and into first via openings 213 and then patterning metal layer 21 and first plated layer 21′ thereon. First conductive traces 215 extend from first insulating layer 211 in the upward direction, extend laterally on first insulating layer 211 and extend into first via openings 213 in the downward direction to form first conductive vias 217 in direct contact with contact pads 312 of semiconductor device 31 and patterned conductive layer 413 of stiffener 41. As a result, first conductive traces 215 can provide signal routing for semiconductor device 31 and ground connection between ground contact pad of semiconductor device 31 and shielding sidewalls 415 of stiffener 41.

Also shown in FIG. 12 is shielding lid 224 in electrical connection with patterned conductive layer 413 of stiffener 41 by depositing second plated layer 22′ on support plate 15 and into second via openings 223 of dielectric layer 13 that is considered second insulating layer 221 to form second conductive vias 227 in electrical contact with patterned conductive layer 413. Shielding lid 224 extends from second insulating layer 221 in the downward direction, laterally extends on second insulating layer 221, and is electrically connected to ground contact pad of semiconductor device 31 through second conductive vias 227, conductive layer 413 and first conductive traces 215.

Accordingly, as shown in FIG. 12, wiring board 200 is accomplished and includes stopper 113, semiconductor device 31, stiffener 41 and dual build-up circuitries 201, 202. In this illustration, first build-up circuitry 201 covers stopper 113, semiconductor device 31 and stiffener 41 in the upward direction and includes first insulating layer 211 and first conductive traces 215, while second build-up circuitry 202 covers stopper 113, semiconductor device 31 and stiffener 41 in the downward direction and includes second insulating layer 221, shielding lid 224 and second conductive vias 227. First build-up circuitry 201 provides signal routing for semiconductor device 31 and ground connection for shielding sidewalls 415 of stiffener 41 as a horizontal shield by first conductive traces 215. Second build-up circuitry 202 provides shielding lid 224 as a vertical shield for semiconductor device 31 and ground connection between conductive layer 413 and shielding lid 224 by second conductive vias 227.

### Embodiment 3

FIGS. 13-15 are cross-sectional views showing a method of making yet another wiring board that includes a shielding lid in electrical connection with a patterned conductive layer of a stiffener through conductive trenches in accordance with yet another embodiment of the present invention.

For purposes of brevity, any description in above Embodiments is incorporated herein insofar as the same is applicable, and the same description need not be repeated.

FIG. 13 is a cross-sectional view of the structure which is manufactured by the same steps shown in FIGS. 9-10.

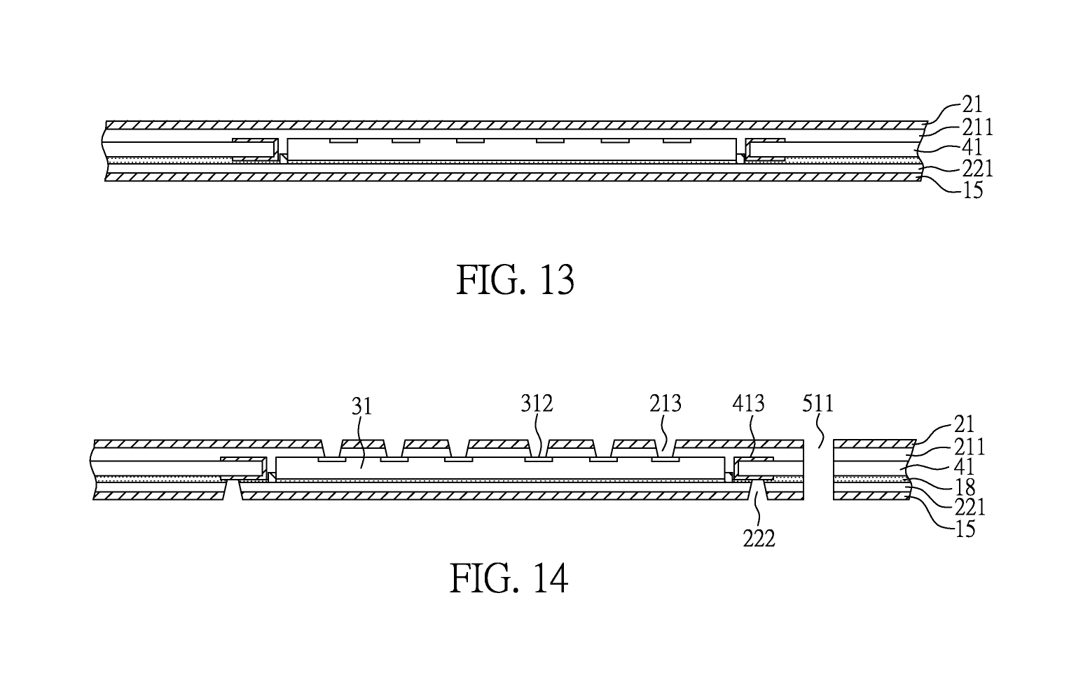

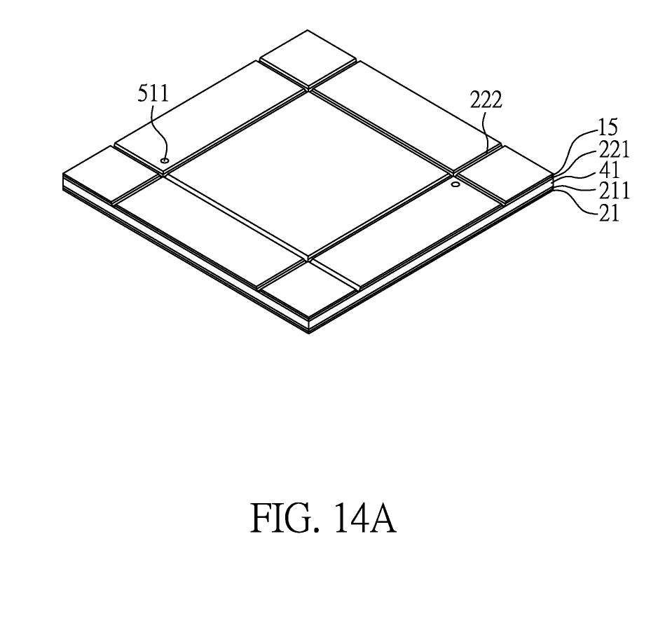

FIGS. 14 and 14A are cross-sectional and bottom perspective views, respectively, of the structure provided with first via openings 213, trench openings 222 and through hole 511. First via openings 213 extend through first insulating layer 211 and metal layer 21 to expose contact pads 312 of semiconductor device 31 in the upward direction. Trench openings 222 extend through support plate 15, second insulating layer 221 and adhesive 18 to expose selected portions of patterned conductive layer 413 in the downward direction. Through holes 511 extend through support plate 15, second insulating layer 221, adhesive 18, stiffener 41, first insulating layer 211 and metal layer 21, and are spaced from patterned conductive layer 413 of stiffener 41. As shown in FIG. 14A, trench openings 222 are formed by mechanically cutting through support plate 15, second insulating layer 221 and adhesive 18 along four cutting lines aligned with patterned conductive layer 413 of stiffener 41.

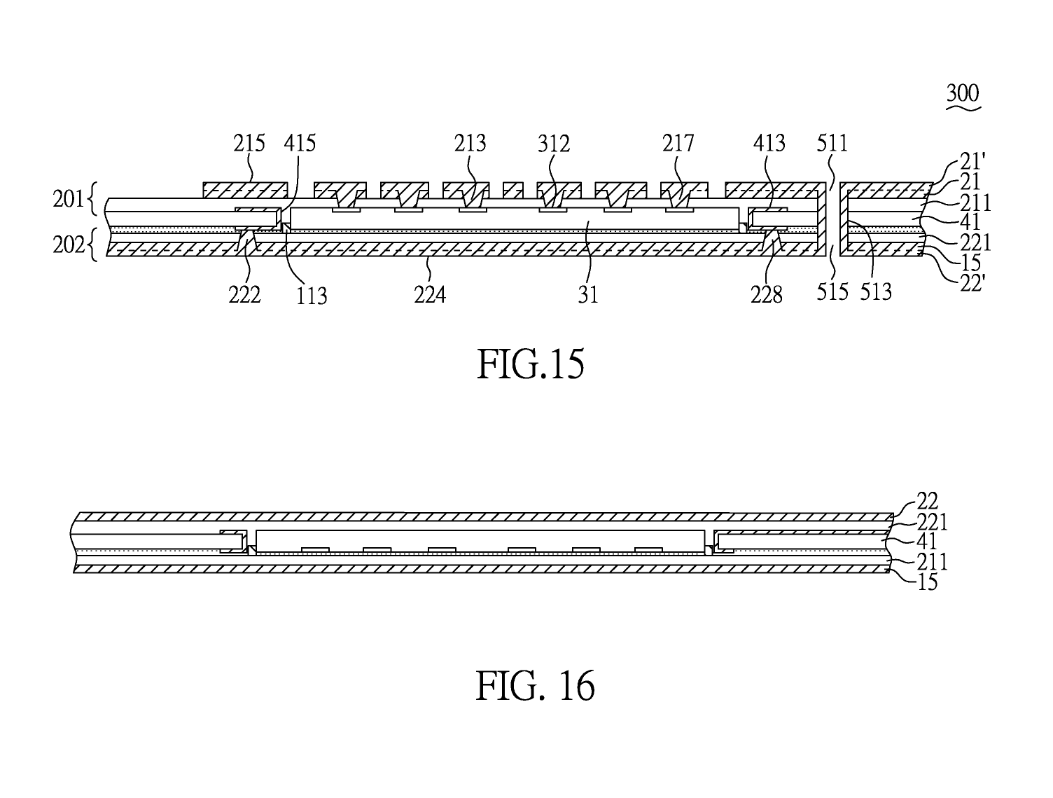

Referring now to FIG. 15, first conductive traces 215 are formed on first insulating layer 211 by depositing first plated layer 21′ on metal layer 21 and into first via openings 213 and then patterning metal layer 21 and first plated layer 21′ thereon. First conductive traces 215 extend from first insulating layer 211 in the upward direction, extend laterally on first insulating layer 211 and extend into first via openings 213 in the downward direction to form first conductive vias 217 in direct contact with contact pads 312. Also shown in FIG. 15 is shielding lid 224 in electrical connection with patterned conductive layer 413 and first conductive traces 215 by depositing second plated layer 22′ on support plate 15 and into trench openings 222 to form conductive trenches 228 in electrical contact with shielding lid 224 and patterned conductive layer 413 and depositing connecting layer 513 in through holes 511 to provide plated through holes 515 in electrical contact with shieling lid 224 and first conductive traces 215.

Accordingly, as shown in FIG. 15, wiring board 300 is accomplished, in which the electrical connection between shielding sidewalls 415 and shielding lid 224 is provided by conductive trenches 228. In this illustration, first build-up circuitry 201 covers stopper 113, semiconductor device 31 and stiffener 41 in the upward direction and includes first insulating layer 211 and first conductive traces 215, while second build-up circuitry 202 covers stopper 113, semiconductor device 31 and stiffener 41 in the downward direction and includes second insulating layer 221, shielding lid 224 and conductive trenches 228. Shielding lid 224 is electrically connected to ground contact pads of semiconductor device 31 through plated through holes 515 and first conductive traces 215. Shielding sidewalls 415 of stiffener 41 are electrically connected to ground contact pads of semiconductor device 31 through patterned conductive layer 413, conductive trenches 228, shielding lid 224, plated through holes 515 and first conductive traces 215.

### Embodiment 4

FIGS. 16-21 are cross-sectional views showing a method of making further another wiring board in which dual build-up circuitries include additional insulating layers and conductive traces and are electrically connected to one another by plated through holes in accordance with further another embodiment of the present invention.

For purposes of brevity, any description in above Embodiments is incorporated herein insofar as the same is applicable, and the same description need not be repeated.

FIG. 16 is a cross-sectional view of the structure which is manufactured by the same steps shown in FIGS. 1-6.

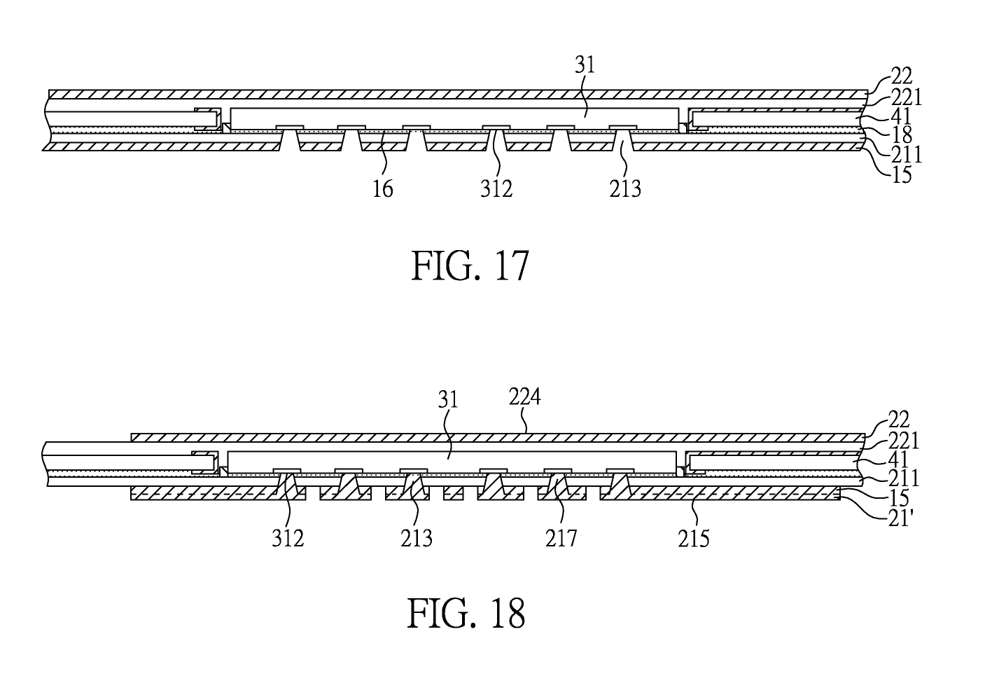

FIG. 17 is a cross-sectional view of the structure provided with first via openings 213. First via openings 213 extend through support plate 15, first insulating layer 211 and adhesive 16 to expose contact pads 312 of semiconductor device 31 in the downward direction.

Referring now to FIG. 18, first conductive traces 215 are formed on first insulating layer 211 by depositing first plated layer 21′ on support plate 15 and into first via openings 213 and then patterning support plate 15 and first plated layer 21′ thereon. First conductive traces 215 extend from first insulating layer 211 in the downward direction, extend laterally on first insulating layer 211 and extend into first via openings 213 in the upward direction to form first conductive vias 217 in direct contact with contact pads 312. Further, the selected portion of metal layer 22 is removed, and the remaining portion of metal layer 22 serves as shielding lid 224 for semiconductor device 31.

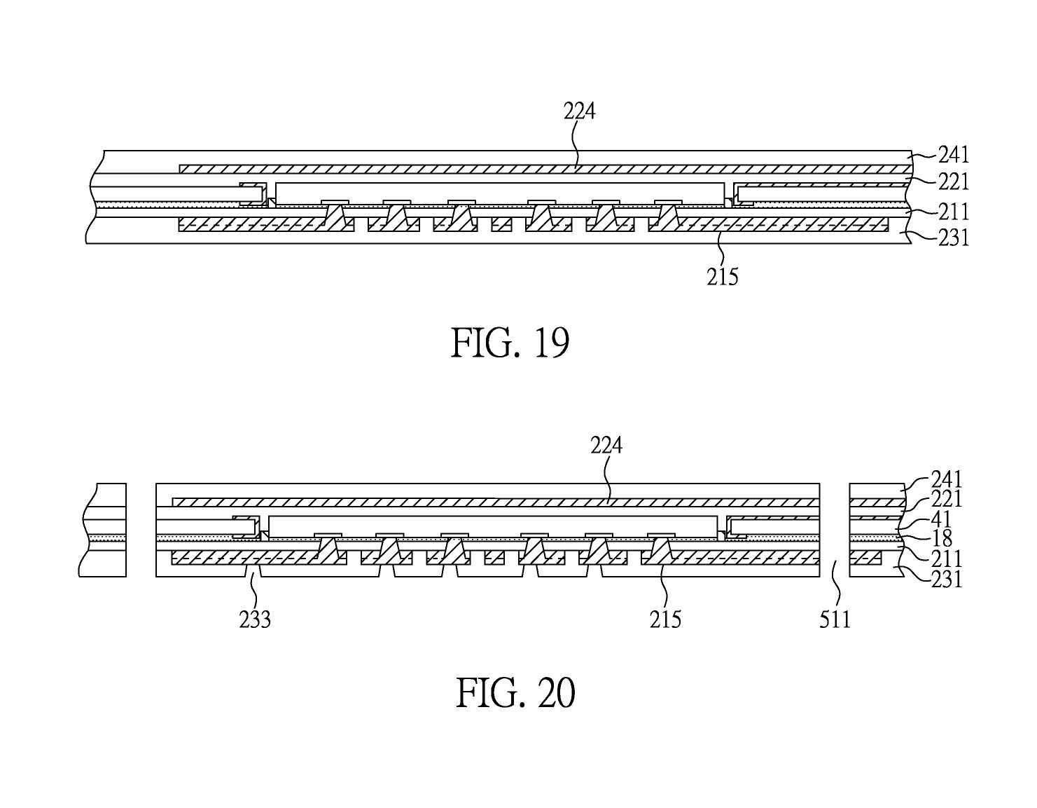

FIG. 19 is a cross-sectional view of the structure provided with third insulating layer 231 and fourth insulating layer 241. Third insulating layer 231 covers first insulating layer 211 and first conductive traces 215 in the downward direction. Fourth insulating layer 241 covers second insulating layer 221 and shielding lid 224 in the upward direction.

FIG. 20 is a cross-sectional view of the structure provided with third via openings 233 and through holes 511. Third via openings 233 extend through third insulating layer 231 and are aligned with selected portions of first conductive traces 215. Through hole 511 extends through fourth insulating layer 241, shielding lid 224, second insulating layer 221, stiffener 41, adhesive 18, first insulating layer 211, first conductive traces 215 and third insulating layer 231 in the vertical direction.

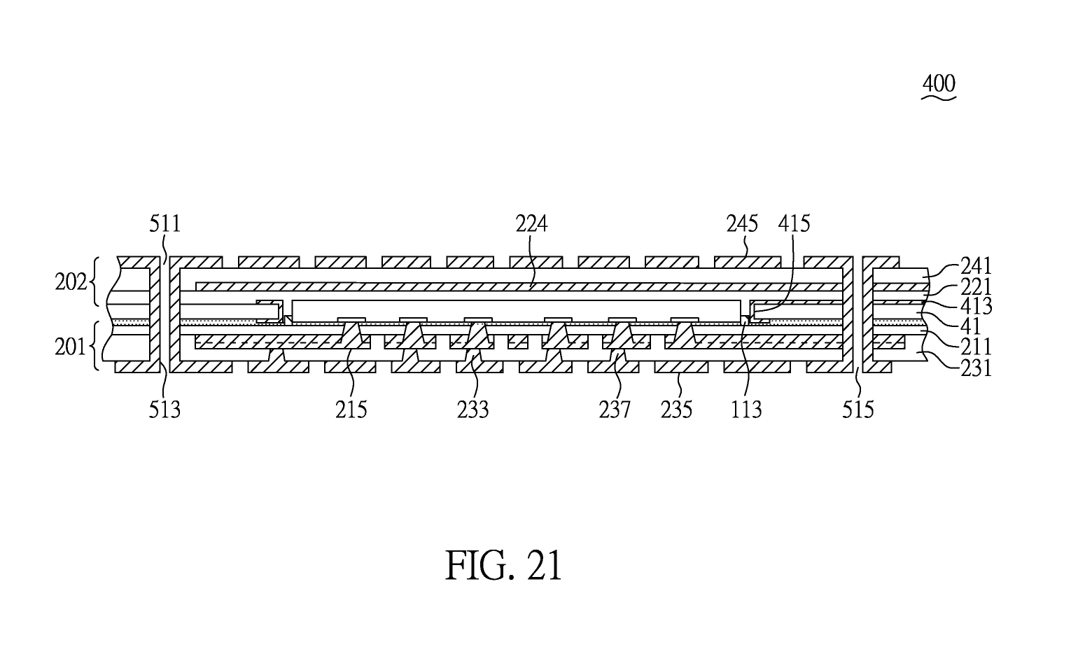

Referring now to FIG. 21, third conductive traces 235 and fourth conductive traces 245 are respectively formed on third and fourth insulating layers 231, 241 by metal deposition and patterning. Third conductive traces 235 extend from third insulating layer 231 in the downward direction, extend laterally on third insulating layer 231 and extend into third via openings 233 in the upward direction to form third conductive vias 237 in electrical contact with first conductive traces 215. Fourth conductive traces 245 extend from fourth insulating layer 241 in the upward direction and extend laterally on fourth insulating layer 241. Also, connecting layer 513 is deposited on the inner wall of through holes 511 to provide plated through holes 515.

Accordingly, as shown in FIG. 21, wiring board 400 is accomplished and includes stopper 113, semiconductor device 31, stiffener 41, dual build-up circuitries 201, 202 and plated through holes 515. In this illustration, first build-up circuitry 201 includes first insulating layer 211, first conductive traces 215, third insulating layer 231 and third conductive traces 235, while second build-up circuitry 202 includes second insulating layer 221, shielding lid 224, fourth insulating layer 241 and fourth conductive traces 245. Plated through holes 515 are essentially shared by stiffener 41, first build-up circuitry 201 and second build-up circuitry 202, and provide electrical connection between third conductive traces 235 and fourth conductive traces 245. Semiconductor device 31 is affixed on first insulating layer 211 and is laterally enclosed by shielding sidewalls 415 of stiffener 41. Shielding sidewalls 415 are electrically connected to ground contact pad of semiconductor device 31 by patterned conductive layer 413, plated through hole 515 and first build-up circuitry 201 and serves as a horizontal shield for semiconductor device 31. Shielding lid 224 is electrically connected to ground contact pad of semiconductor device 31 by plated through hole 515 and first build-up circuitry 201 and serves as a vertical shield for semiconductor device 31.

### Embodiment 5

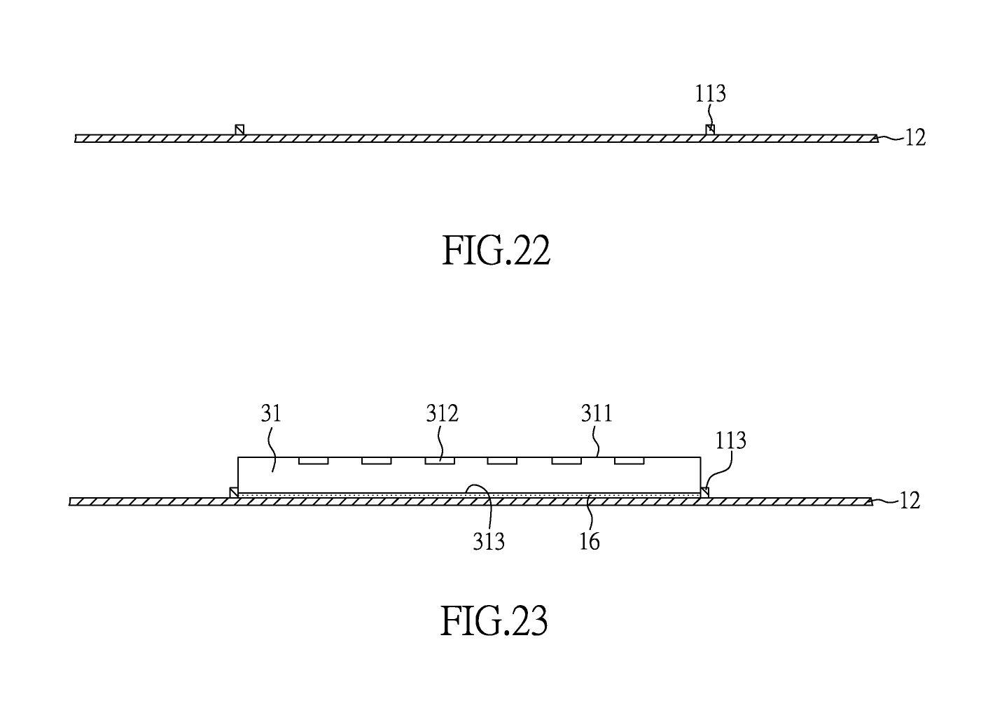

FIGS. 22-28 are cross-sectional views showing another method of making a wiring board that includes a stopper, a shielding lid, a semiconductor device, a stiffener, a build-up circuitry, conductive trenches, terminals and plated through holes in accordance with an embodiment of the present invention.

For purposes of brevity, any description in above Embodiments is incorporated herein insofar as the same is applicable, and the same description need not be repeated.

FIG. 22 is a cross-sectional view of the structure with stopper 113 formed on metal layer 12. Stopper 113 can be pattern deposited on metal layer 12 by numerous techniques including electroplating, electroless plating, evaporating, sputtering and their combinations using photolithographic process. Metal layer 12 is illustrated as a copper plate with a thickness of 35 microns. Stopper 113 is illustrated as a continuous copper strip in a rectangular frame arrangement with a thickness of 35 microns.

FIG. 23 is a cross-sectional view of the structure with semiconductor device 31 mounted on metal layer 12 using adhesive 16 that is sandwiched between and contacts metal layer 12 and semiconductor device 31. Semiconductor device 31 includes active surface 311 with contact pads 312 thereon and inactive surface 313, and is attached onto metal layer 12 with its inactive surface 313 facing metal layer 12. Stopper 113 extends from metal layer 12 and extends beyond inactive surface 313 of semiconductor device 31 in the upward direction and is in close proximity to peripheral edges of semiconductor device 31 to serve as a placement guide for semiconductor device 31. As a result, semiconductor device 31 can be precisely confined at predetermined location.

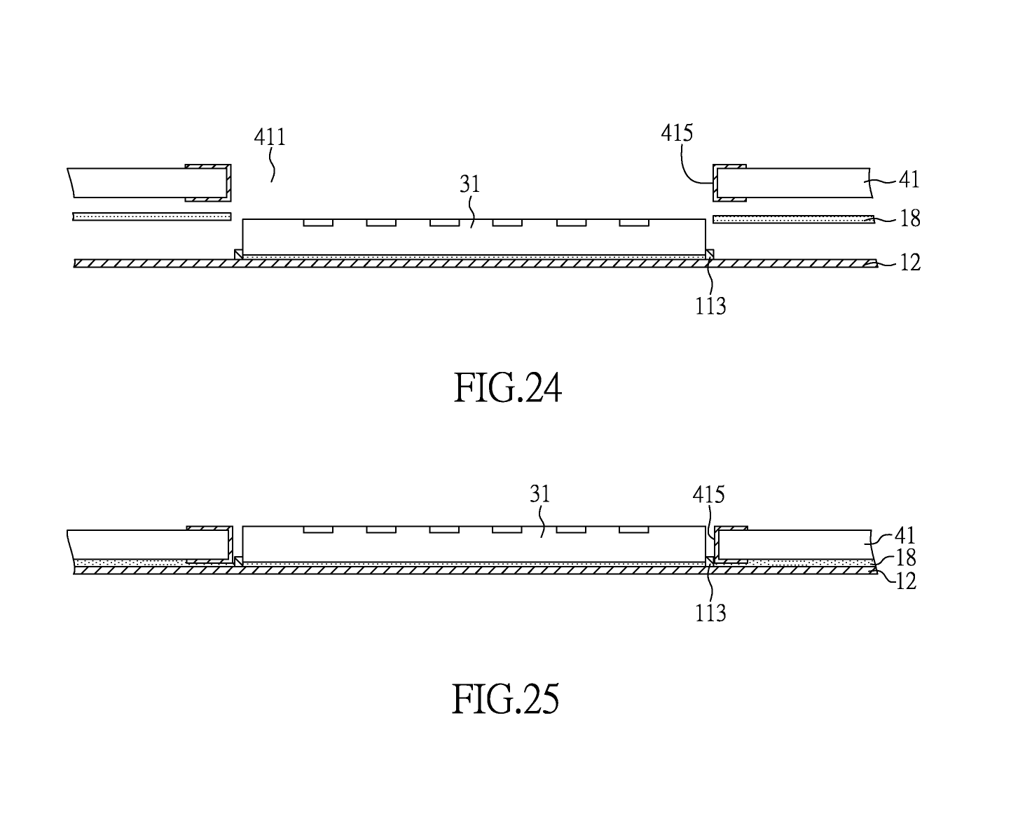

FIGS. 24 and 25 are cross-sectional views showing the process of mounting stiffener 41 on metal layer 12 using adhesive 18 that is sandwiched between and contacts metal layer 12 and stiffener 41. Semiconductor device 31 and stopper 113 are aligned with and inserted into aperture 411 of stiffener 41, and shielding sidewalls 415 of aperture 411 are spaced from semiconductor device 31 by stopper 113. Stopper 113 is in close proximity to and laterally aligned with four shielding sidewalls 415 of aperture 411, and thus any undesirable movement of stiffener 41 also can be avoided before adhesive 18 is fully cured. In this embodiment, stiffener 41 is coplanar with semiconductor device 31 in the upward and downward directions.

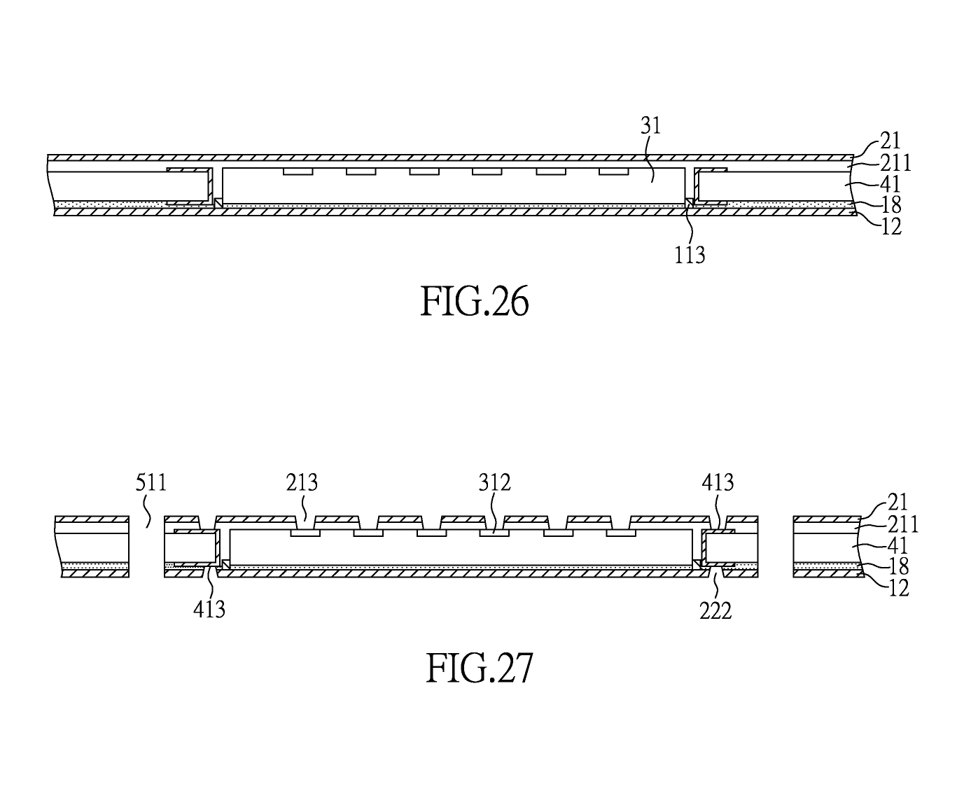

FIG. 26 is a cross-sectional view of the structure provided with first insulating layer 211 and metal layer 21. First insulating layer 211 is sandwiched between metal layer 21 and semiconductor device 31 and between metal layer 21 and stiffener 41, and further extends into the gap between semiconductor device 31 and stiffener 41.

FIG. 27 is a cross-sectional view of the structure provided with first via openings 213, trench openings 222 and through holes 511. First via openings 213 extend through metal layer 21 and first insulating layer 211 and are aligned with contact pads 312 of semiconductor device 31 and selected portions of conductive layer 413. Trench openings 222 extend through metal layer 12 and adhesive 18 and are aligned with selected portions of conductive layer 413. Through holes 511 extend through metal layer 12, adhesive 18, stiffener 41, first insulating layer 211 and metal layer 21 in the vertical direction.

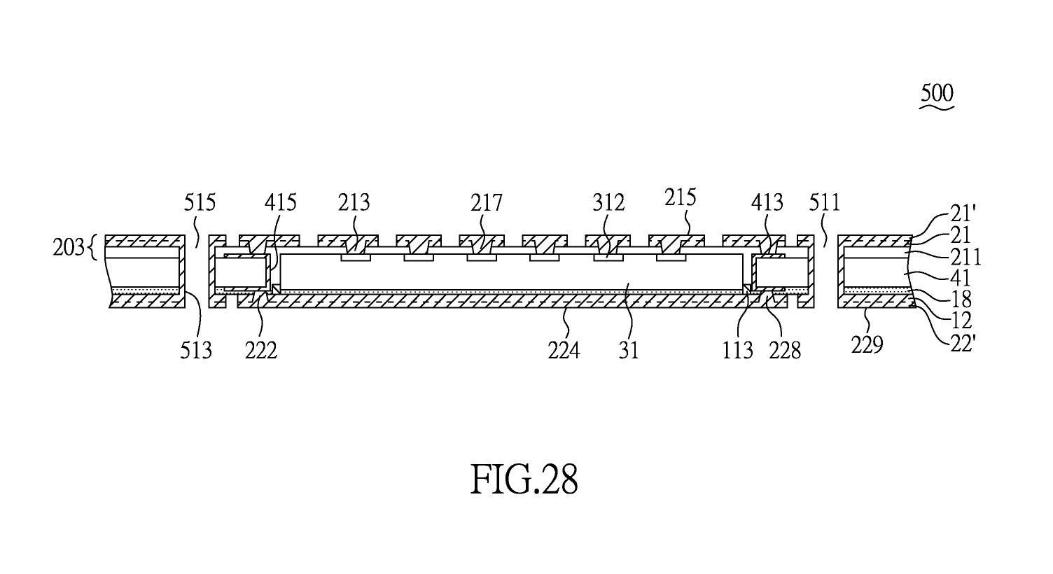

Referring now to FIG. 28, first conductive traces 215 are formed on first insulating layer 211 by depositing first plated layer 21′ on metal layer 21 and into first via openings 213 and then patterning metal layer 21 and first plated layer 21′ thereon. First conductive traces 215 provide signal routing for semiconductor device 31 and ground connection for shielding sidewalls 415 of stiffener 41 by first conductive vias 217 in direct contact with patterned conductive layer 413.

Also shown in FIG. 28 are shielding lid 224 in electrical contact with conductive layer 413 by conductive trenches 228 and terminals 229 in electrical contact with first conductive traces 215 by plated through holes 515. Shielding lid 224 and terminals 229 are formed by depositing second plated layer 22′ on metal layer 12 and then patterning metal layer 12 and second plated layer 22′ thereon. Shielding lid 224 covers semiconductor device 31 and stopper 113 in the downward direction and is electrically connected to patterned conductive layer 413 by conductive trenches 228. Terminals 229 are spaced from shielding lid 224 and electrically connected to first conductive traces 215 by plated through holes 515. Plated through holes 515 are provided by depositing connecting layer 513 in through hole 511.

Accordingly, as shown in FIG. 28, wiring board 500 is accomplished and includes stopper 113, shielding lid 224, semiconductor device 31, stiffener 41, build-up circuitry 203, conductive trenches 228, terminals 229 and plated through holes 515. In this illustration, build-up circuitry 203 includes first insulating layer 211 and first conductive traces 215, and plated through holes 515 are essentially shared by stiffener 41, build-up circuitry 203 and terminal 226. Semiconductor device 31 is affixed on shielding lid 224 and is laterally enclosed by shielding sidewalls 415 of stiffener 41 in lateral directions. Shielding sidewalls 415 are electrically connected to ground contact pad of semiconductor device 31 by build-up circuitry 203 and can serve as a horizontal shield for semiconductor device 31. Shielding lid 224 is electrically connected to ground contact pad of semiconductor device 31 by conductive trenches 228, conductive layer 413 and build-up circuitry 203 and can serve as a vertical shield for semiconductor device 31. Plated through holes 515 provide electrical connection between build-up circuitry 203 and terminals 229 that extend beyond stiffener 41 in the downward direction.

### Embodiment 6

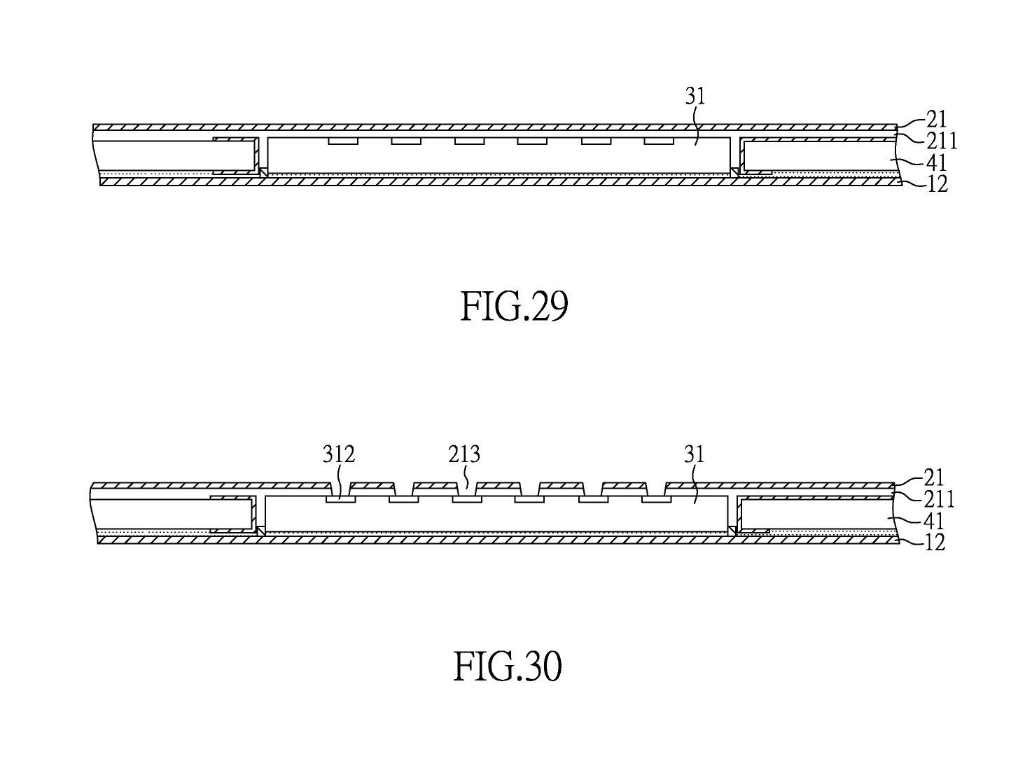

FIGS. 29-34 are cross-sectional views showing a method of making another wiring board that includes a stopper, a shielding lid, a semiconductor device, a stiffener, dual build-up circuitries and plated through holes in accordance with another embodiment of the present invention.

For purposes of brevity, any description in above Embodiments is incorporated herein insofar as the same is applicable, and the same description need not be repeated.

FIG. 29 is a cross-sectional view of the structure which is manufactured by the steps shown in FIGS. 22-26.

FIG. 30 is a cross-sectional view of the structure provided with first via openings 213. First via openings 213 extend through metal layer 21 and first insulating layer 211 to expose contact pads 312 of semiconductor device 31.

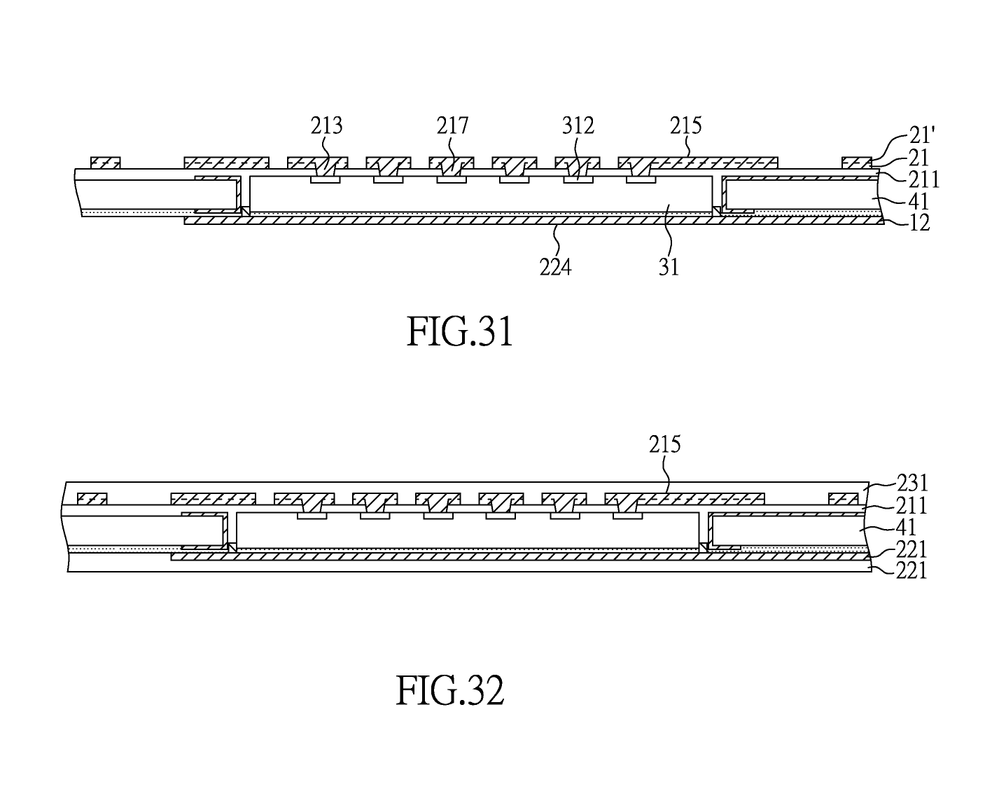

Referring now to FIG. 31, first conductive traces 215 are formed on first insulating layer 211 by depositing first plated layer 21′ on metal layer 21 and into first via openings 213 and then patterning metal layer 21 and first plated layer 21′ thereon. Also, the selected portion of metal layer 12 is removed, and the remaining portion of metal layer 12 serves as shielding lid 224 to provide vertical EMI shielding effect for semiconductor device 31.

FIG. 32 is a cross-sectional view of the structure provided with second insulating layer 221 and third insulating layer 231. Second insulating layer 221 covers shielding lid 224 in the downward direction. Third insulating layer 231 covers first insulating layer 211 and first conductive traces 215 in the upward direction.

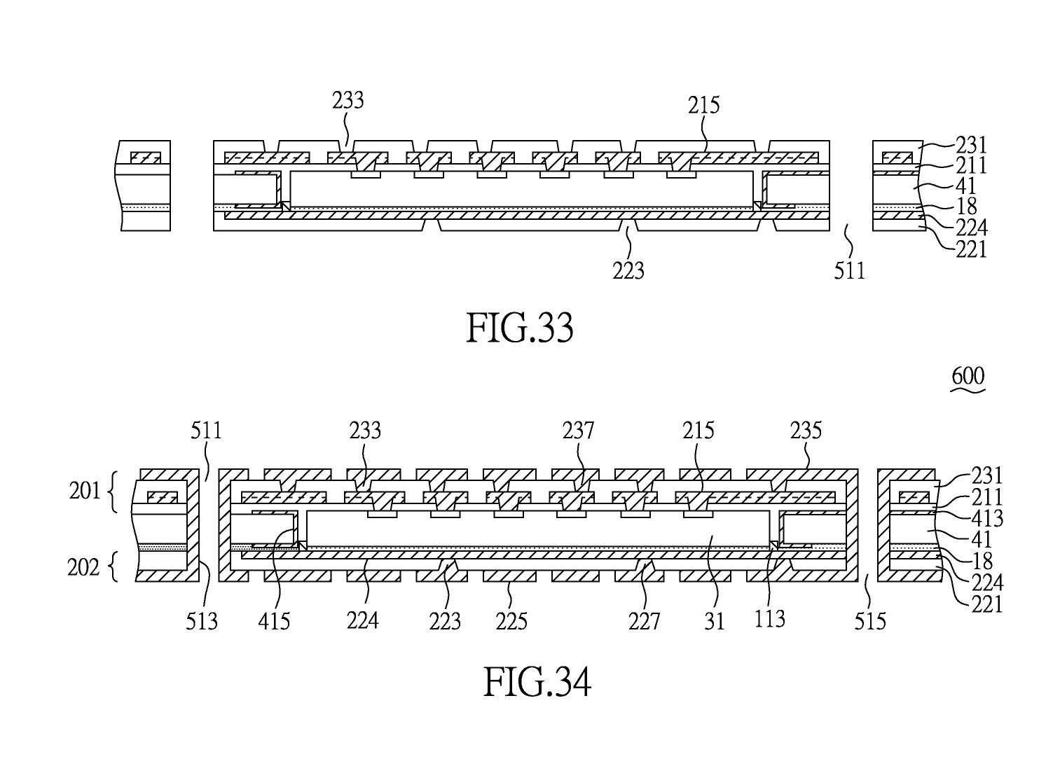

FIG. 33 is a cross-sectional view of the structure provided with second via openings 223, third via openings 233 and through holes 511. Second via openings 223 extend through second insulating layer 221 and are aligned with selected portions of shielding lid 224. Third via openings 233 extend through third insulating layer 231 and are aligned with selected portions of first conductive traces 215. Through hole 511 extends through second insulating layer 221, shielding lid 224, adhesive 18, stiffener 41, first insulating layer 211 and third insulating layer 231 in the vertical direction.

Referring now to FIG. 34, second conductive traces 225 and third conductive traces 235 are respectively formed on second and third insulating layers 221, 231 by metal deposition and patterning. Second conductive traces 225 extend from second insulating layer 221 in the downward direction, extend laterally on second insulating layer 221, and extend into second via openings 223 in the upward direction to form second conductive vias 227 in electrical contact with shielding lid 224. Third conductive traces 235 extend from third insulating layer 231 in the upward direction, extend laterally on third insulating layer 231 and extend into third via openings 233 in the downward direction to form third conductive vias 237 in electrical contact with first conductive traces 215. Also, connecting layer 513 is deposited on the inner wall of through holes 511 to provide plated through holes 515.

Accordingly, as shown in FIG. 34, wiring board 600 is accomplished and includes stopper 113, shielding lid 224, semiconductor device 31, stiffener 41, dual build-up circuitries 201, 202 and plated through holes 515. In this illustration, first build-up circuitry 201 includes first insulating layer 211, first conductive traces 215, third insulating layer 231 and third conductive traces 235, while second build-up circuitry 202 includes second insulating layer 221 and second conductive traces 225. Plated through holes 515 are essentially shared by stiffener 41, shielding lid 224, first build-up circuitry 201 and second build-up circuitry 202, and provide electrical connection between first build-up circuitry 201 and second build-up circuitry 202. Semiconductor device 31 is affixed on shielding lid 224 and is laterally enclosed by shielding sidewalls 415 of stiffener 41. Shielding sidewalls 415 are electrically connected to ground contact pad of semiconductor device 31 by conductive layer 413 of stiffener 41, plated through hole 515 and first build-up circuitry 201 and serves as a horizontal shield for semiconductor device 31. Shielding lid 224 is electrically connected to ground contact pad of semiconductor device 31 by second build-up circuitry 202, plated through hole 515 and first build-up circuitry 201 and serves as a vertical shield for semiconductor device 31.

### Embodiment 7

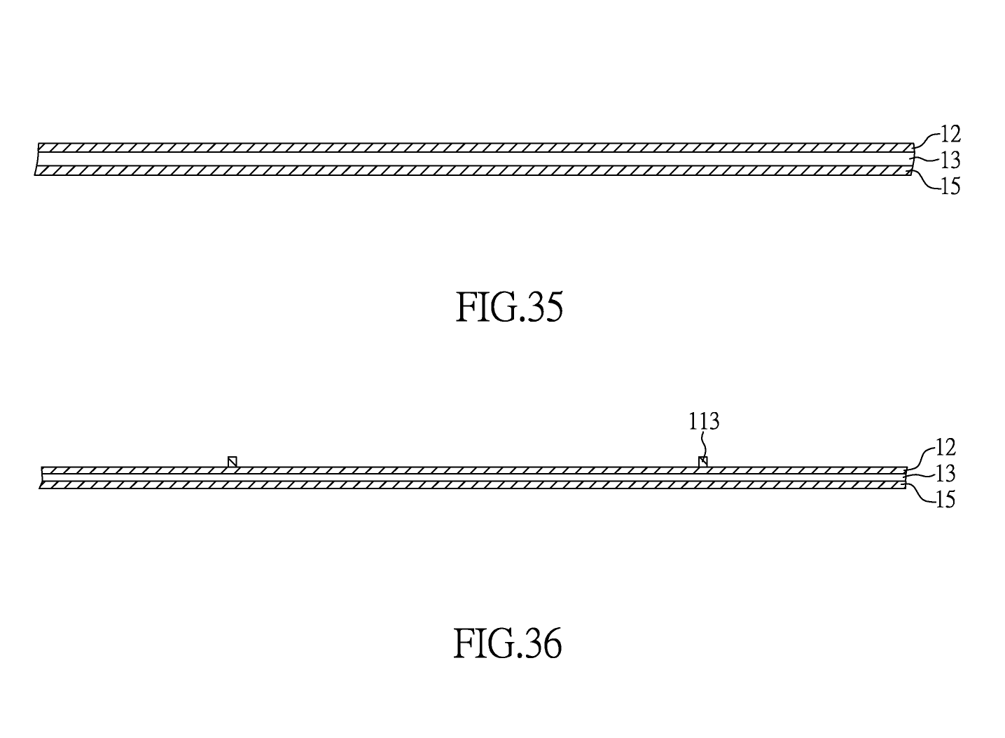

FIGS. 35-42 are cross-sectional views showing a method of making yet another wiring board with the shielding lid inserted into the aperture of the stiffener in accordance with yet another embodiment of the present invention.

For purposes of brevity, any description in above Embodiments is incorporated herein insofar as the same is applicable, and the same description need not be repeated.

FIG. 35 is a cross-sectional view of a laminate substrate that includes metal layer 12, dielectric layer 13 and support plate 15. Dielectric layer 13 is sandwiched between metal layer 12 and support plate 15.

FIG. 36 is a cross-sectional view of the structure with stopper 113 formed on metal layer 12. Stopper 113 can be pattern deposited on metal layer 12 by numerous techniques including electroplating, electroless plating, evaporating, sputtering and their combinations using photolithographic process.

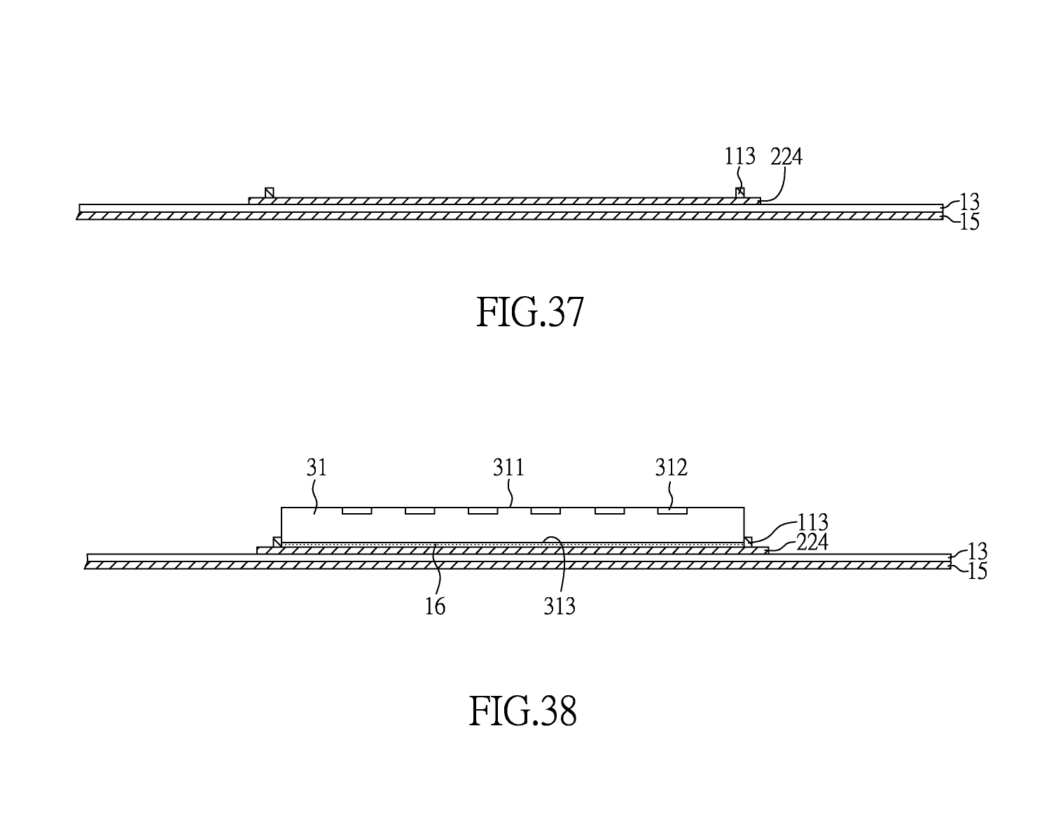

FIG. 37 is a cross-sectional view of the structure with shielding lid 224 defined on dielectric layer 13. Shielding lid 224 can be formed by removing selected portions of metal layer 12 using photolithography and wet etching. Shielding lid 224 corresponds to the predetermined location for placing a semiconductor device and can serve as a vertical EMI shield.

FIG. 38 is a cross-sectional view of the structure with semiconductor device 31 mounted on shielding lid 224 using adhesive 16 using adhesive 16 that is sandwiched between and contacts shielding lid 224 and semiconductor device 31. Semiconductor device 31 includes active surface 311 with contact pads 312 thereon and inactive surface 313, and is attached onto shielding lid 224 with its inactive surface 313 facing shielding lid 224. Stopper 113 extends from shielding lid 224 and extends beyond inactive surface 313 of semiconductor device 31 in the upward direction and is in close proximity to peripheral edges of semiconductor device 31 to serve as a placement guide for semiconductor device 31.

FIG. 39 is a cross-sectional view of the structure with stiffener 41 mounted on dielectric layer 13 using adhesive 18. Semiconductor device 31, stopper 113 and shielding lid 224 are aligned with and inserted into aperture 411 of stiffener 41, and stiffener 41 is mounted on exposed dielectric layer 13 using adhesive 18. In this illustration, the peripheral edges of shielding lid 224 is in close proximity to and laterally aligned with four shielding sidewalls 415 of aperture 411 and adhesive 18 under stiffener 41 is lower than shielding lid 224, and thus any undesirable movement of stiffener 41 also can be avoided before adhesive 18 is fully cured. Alternatively, in some embodiments, stiffener 41 may be attached on exposed dielectric layer 13 as well as selected portions of shielding lid 224 that laterally extend beyond the area underneath semiconductor device 31, and undesirable movement of stiffener 41 is blocked by stopper 113 that is in close proximity to and laterally aligned with four shielding sidewalls 415 of aperture 411. Optionally, a bonding material (not shown in the figure) can be added between semiconductor device 31 and stiffener 41 to enhance rigidity.

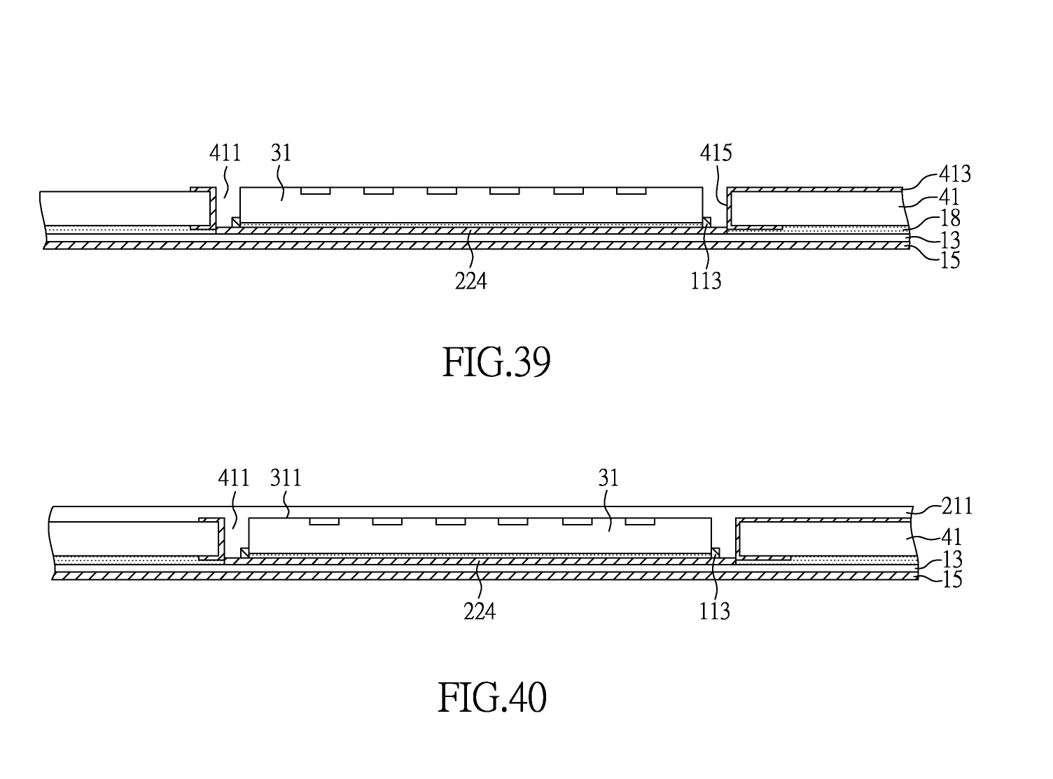

FIG. 40 is a cross-sectional view of the structure with first insulating layer 211 formed on active surface 311 of semiconductor device 31 and stiffener 41 in the upward direction. First insulating layer 211 covers semiconductor device 31 and stiffener 41 in the upward direction, and extends into the gap between semiconductor device 31 and stiffener 41 in aperture 411.

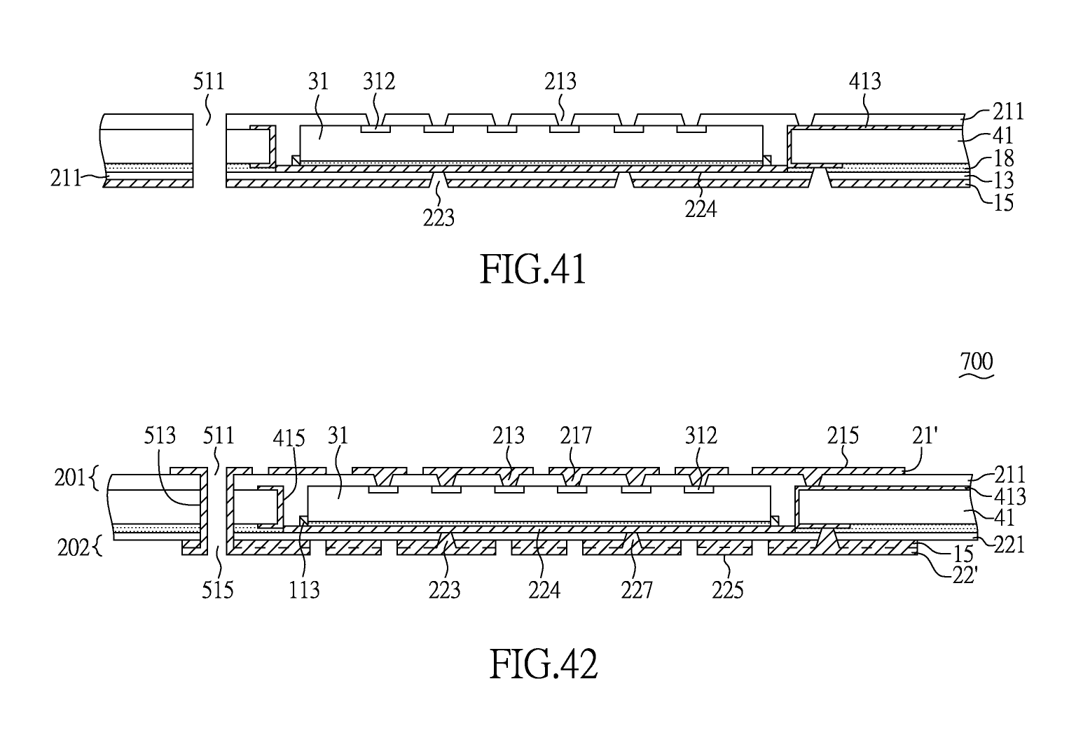

FIG. 41 is a cross-sectional view of the structure provided with first via openings 213, second via openings 223 and through hole 511. First via openings 213 extend through first insulating layer 211 to expose contact pads 312 of semiconductor device 31 and selected portions of conductive layer 413. Second via openings 223 extend through support plate 15 and dielectric layer 13 that is considered second insulating layer 221 to expose selected portions of shielding lid 224 and conductive layer 413. Through hole 511 extends through first insulating layer 211, stiffener 41, adhesive 18, dielectric layer 13 and support plate 15 in the vertical direction.

Referring now to FIG. 42, first conductive traces 215 are formed on first insulating layer 211 by depositing first plated layer 21′ on first insulating layer 211 and into first via openings 213, and then patterning first plated layer 21′. Meanwhile, second conductive traces 225 are formed on second insulating later 221 by depositing second plated layer 22′ on support plate 15 and into second via openings 223, and then patterning support plate 15 as well as second plated layer 22′ thereon. Also shown in FIG. 42 is connecting layer 513 deposited on the inner wall of through hole 511 to provide plated through hole 515.

Accordingly, as shown in FIG. 42, wiring board 700 is accomplished and includes stopper 113, shielding lid 224, semiconductor device 31, stiffener 41, dual build-up circuitries 201, 202 and plated through hole 515. In this illustration, first build-up circuitry 201 includes first insulating layer 211 and first conductive traces 215, while second build-up circuitry 202 includes second insulating layer 221 and second conductive traces 225. First conductive traces 215 extend from first insulating layer 211 in the upward direction and extend into first via openings 213 in the downward direction to form first conductive vias 217 in electrical contact with contact pads 312 and conductive layer 413. Second conductive traces 225 extend from second insulating layer 221 in the downward direction and extend into second via openings 223 in the upward direction to form second conductive vias 227 in electrical contact with shielding lid 224 and conductive later 413. Shielding sidewalls 415 are electrically connected to ground contact pad of semiconductor device 31 by conductive layer 413 and first build-up circuitry 201. Shielding lid 224 is electrically connected to ground contact pad of semiconductor device 31 by second build-up circuitry 202, conductive layer 413 and first build-up circuitry 201. Plated through hole 515 is essentially shared by stiffener 41, first build-up circuitry 201 and second build-up circuitry 202, and provide an electrical connection between first conductive traces 215 and second conductive traces 225.

### Embodiment 8

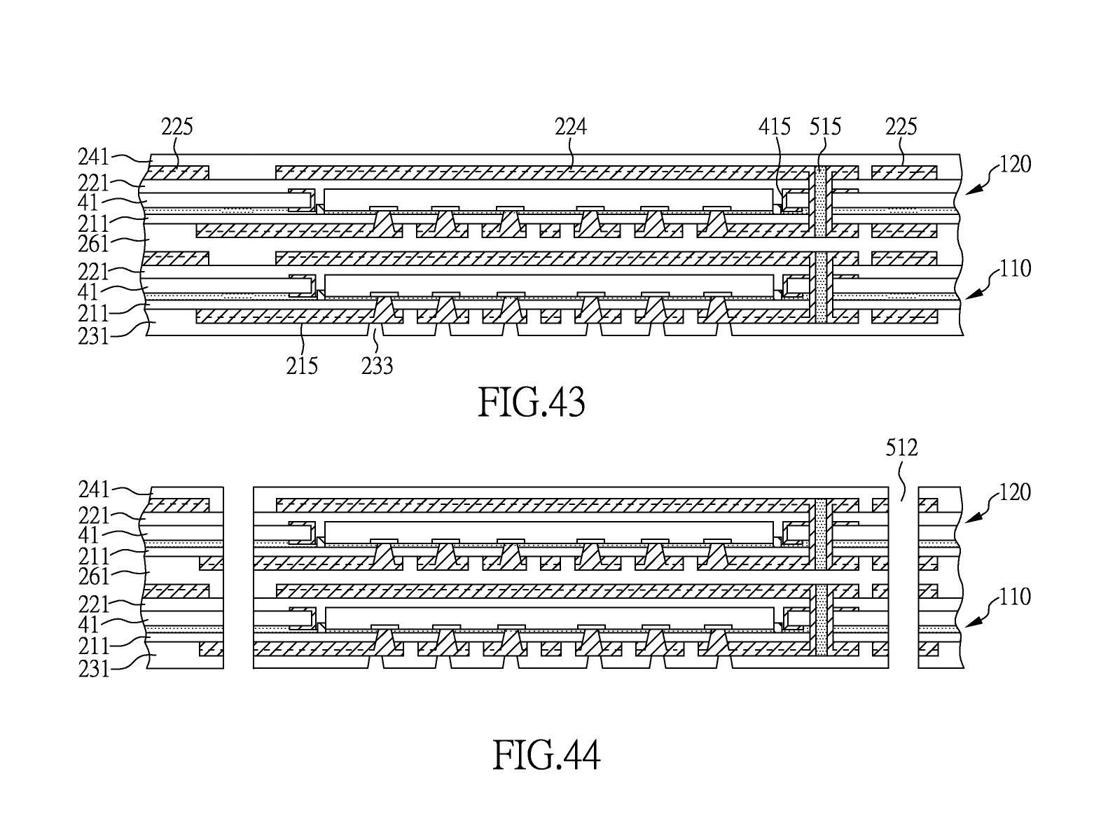

FIGS. 43-45 are cross-sectional views showing a method of making a three-dimensional stacking module that includes plural wiring boards in face-to-back stacking in accordance with one embodiment of the present invention.

For purposes of brevity, any description in above Embodiments is incorporated herein insofar as the same is applicable, and the same description need not be repeated.

FIG. 43 is a cross-sectional view of the structure with interlayer dielectric 261 sandwiched between two neighboring wiring boards 110, 120. Wiring boards 110, 120 are manufactured by the same steps shown in FIGS. 1-8, except that shielding lid 224 is spaced from peripheral edges of wiring boards 110, 120 and second conductive traces 225 are further formed on second insulating layer 221. Wiring boards 110, 120 are vertically stacked and bonded to one another using interlayer dielectric 261 that contacts and is sandwiched between second insulating layer 221/shielding lid 224/second conductive traces 225 of wiring board 110 and first insulating layer 211/first conductive traces 215 of wiring board 120. Further, wiring boards 110, 120 are respectively provided with third insulating layer 231 and fourth insulating layer 241. Third insulating layer 231 covers and contacts first insulating layer 211 and first conductive traces 215 of wiring board 110 in the downward direction, and includes third via openings 233 aligned with selected portions of first conductive traces 215. Fourth insulating layer 241 covers and contacts second insulating layer 221, shielding lid 224 and second conductive traces 225 of wiring board 120 in the upward direction.

FIG. 44 is a cross-sectional view of the structure with through holes 512. Through holes 512 extend through wiring boards 110, 120 and interlayer dielectric 261 in the vertical direction.

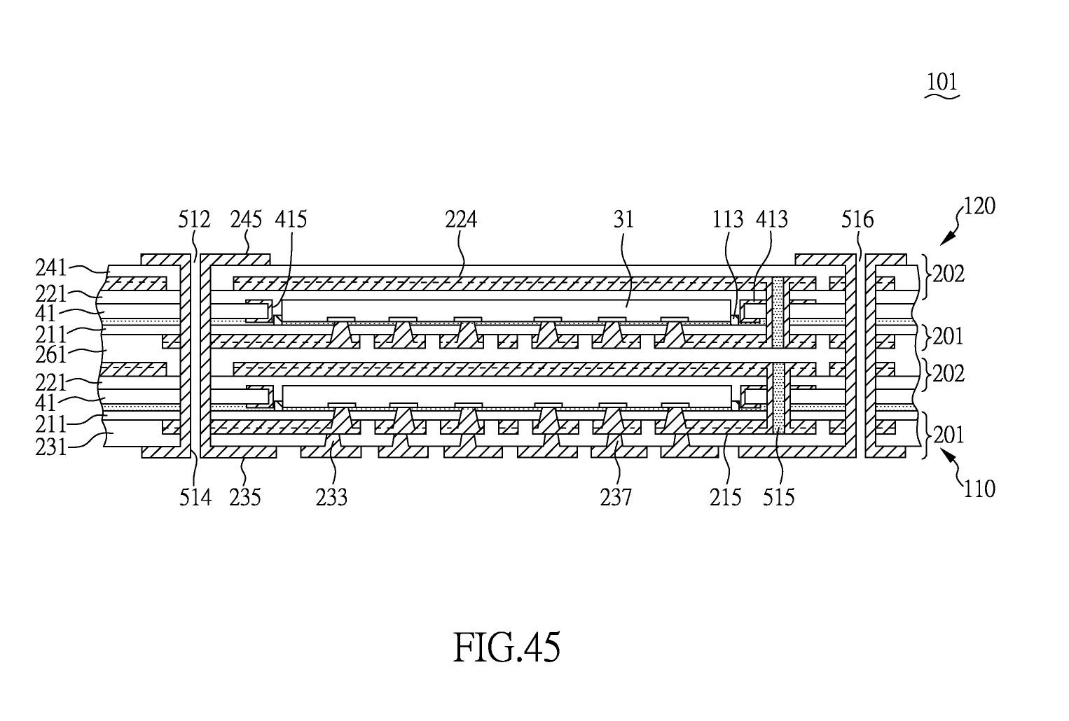

Referring now to FIG. 45, wiring boards 110, 120 are respectively provided with third conductive traces 235 and fourth conductor traces 245. Third conductive traces 235 extend from third insulating layer 231 in the downward direction, extend laterally on third insulating layer 231, and extend into third via openings 233 to form third conductive vias 237 in electrical contact with first conductive traces 215. Fourth conductive traces 245 extend from fourth insulating layer 241 in the upward direction and extend laterally on fourth insulating layer 241. Also shown in FIG. 45 is connecting layer 514 deposited in through holes 512 to provide plated through holes 516. Accordingly, stacking module 101 is accomplished and includes multiple wiring boards 110, 120, interlayer dielectric 261 and plated through holes 516. Each wiring board 110, 120 includes stopper 113, semiconductor device 31, stiffener 41, first build-up circuitry 201, second build-up circuitry 202 and plated through holes 515. Shielding sidewalls 415 of stiffener 41 and shielding lid 224 can be electrically connected to ground contact pads of semiconductor device 31 by plated through hole 515 in electrical contact with conductive layer 413 and shielding lid 224. Plated through holes 516 are essentially shared by wiring boards 110, 120 and extend through interlayer dielectric 261 and wiring boards 110, 120 to provide electrical connection between wiring boards 110, 120.

### Embodiment 9

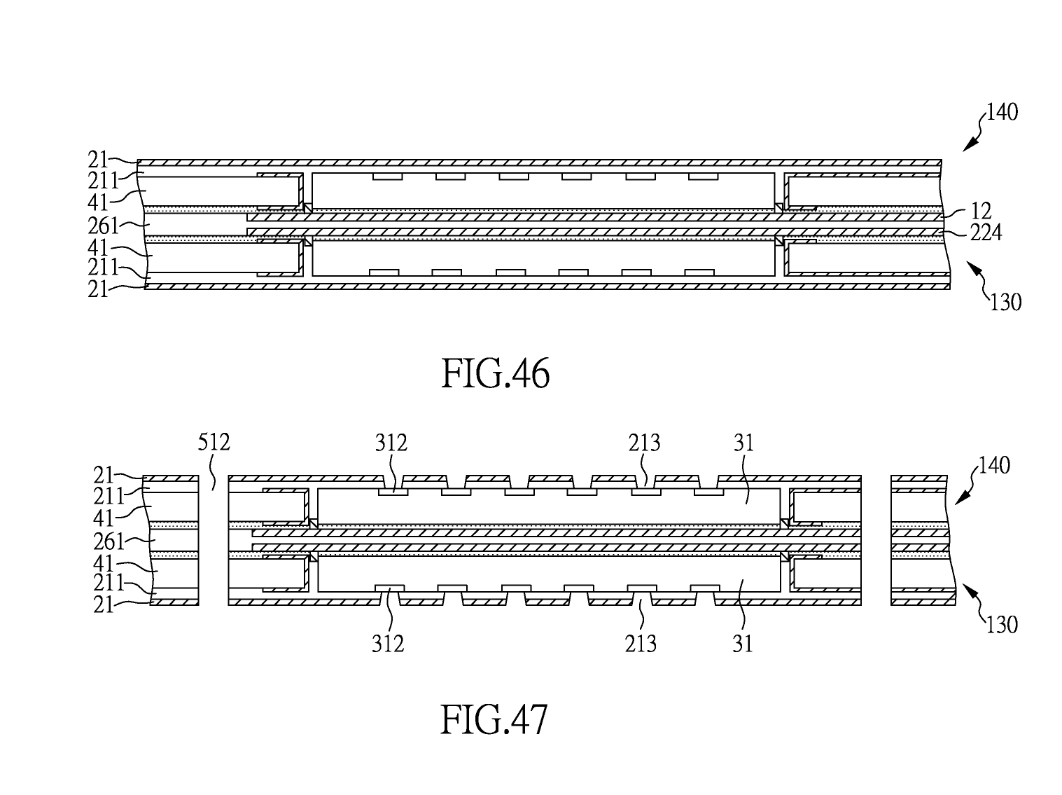

FIGS. 46-48 are cross-sectional views showing a method of making another three-dimensional stacking module that includes plural wiring boards in back-to-back stacking in accordance with another embodiment of the present invention.

For purposes of brevity, any description in above Embodiments is incorporated herein insofar as the same is applicable, and the same description need not be repeated.

FIG. 46 is a cross-sectional view of the structure with interlayer dielectric 261 sandwiched between plural wiring boards 130, 140. Wiring boards 130, 140 are the same as illustrated in FIG. 29, except the selected portion of metal layer 12 is removed and the remaining portion of metal layer 12 serves as shielding lid 224. Wiring boards 130, 140 are vertically stacked in back-to back manner and bonded to one another using interlayer dielectric 261 that is sandwiched between wiring boards 130, 140 and contacts shielding lid 224 of each wiring board 130, 140.

FIG. 47 is a cross-sectional view of the structure with first via openings 213 and through holes 512. First via openings 213 extend through metal layer 21 and first insulating layer 211 to expose contact pads 312 of semiconductor device 31 in each wiring board 130, 140. Through holes 512 extend through wiring boards 130, 140 and interlayer dielectric 261 in the vertical direction.

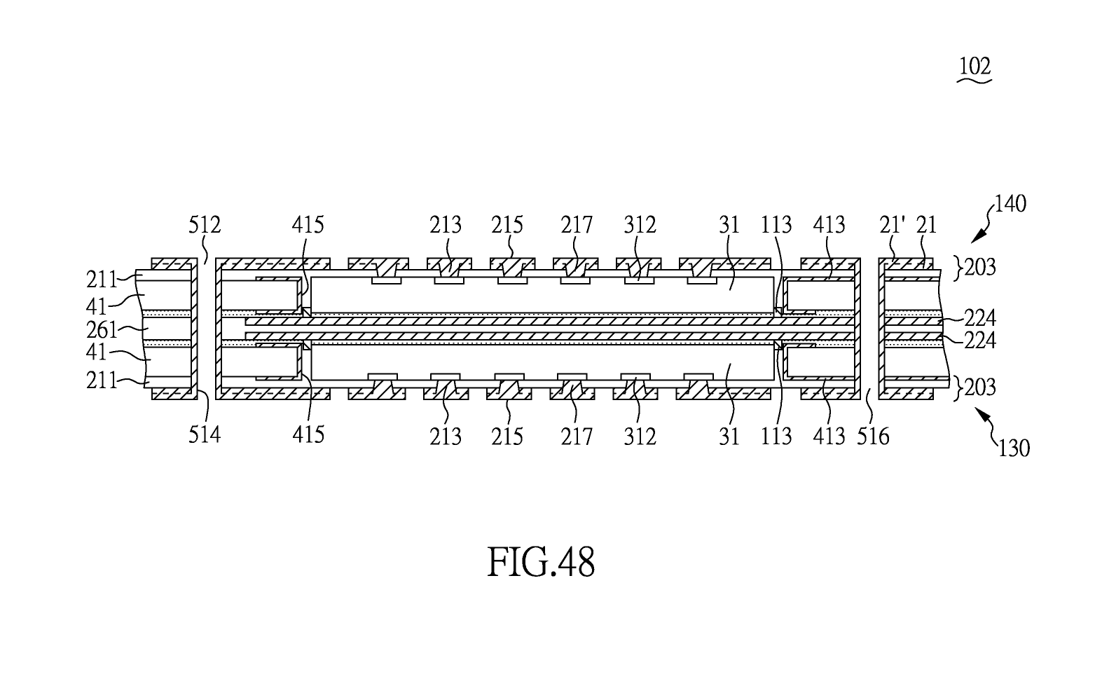

Referring now to FIG. 48, each wiring board 130, 140 is provided with first conductive traces 215 by depositing first plated layer 21′ on metal layer 21 and into first via openings 213 and then patterning metal layer 21 and first plated layer 21′ thereon. First conductive traces 215 extend vertically from first insulating layer 211, extend laterally on first insulating layer 211, and extend into first via openings 213 to form first conductive vias 217 in electrical contact with contact pads 312 of semiconductor device 31. Also shown in FIG. 48 is connecting layer 514 deposited in through holes 512 to provide plated through holes 516. Accordingly, stacking module 102 is accomplished and includes wiring boards 130, 140, interlayer dielectric 261 and plated through holes 516. Each wiring board 130, 140 includes stopper 113, shielding lid 224, semiconductor device 31, stiffener 41 and build-up circuitry 203. Shielding sidewalls 415 of stiffener 41 and shielding lid 224 can be electrically connected to ground contact pads of semiconductor device 31 by plated through hole 516 in electrical contact with conductive layer 413 and shielding lid 224. Plated through holes 516 are essentially shared by wiring boards 130, 140 and extend through interlayer dielectric 261 and wiring boards 130, 140 to provide electrical connection between wiring boards 130, 140.

The wiring boards and three-dimensional stacking modules described above are merely exemplary. Numerous other embodiments are contemplated. In addition, the embodiments described above can be mixed-and-matched with one another and with other embodiments depending on design and reliability considerations. The wiring board can include multiple shielding lids and apertures with shielding sidewalls arranged in an array for multiple side-by-side semiconductor devices and the build-up circuitries can include additional conductive traces to accommodate additional semiconductor devices, shielding sidewalls and shielding lids. Likewise, the wiring board can include multiple sets of stoppers to accommodate multiple additional semiconductor devices.

The semiconductor device can be a packaged or unpackaged chip. Furthermore, the semiconductor device can be a bare chip, or a wafer level packaged die, etc. The stopper, the shielding lid and the aperture with shielding sidewalls can be customized to accommodate a single semiconductor device. For instance, the stopper can have a pattern that defines a square or rectangular area with the same or similar topography as a single semiconductor device, and the aperture can have a square or rectangular shape with the same or similar topography and dimension as a single semiconductor device. Likewise, the shielding lid also can be customized to have a shape with the same or similar topography as a single semiconductor device.

The term “adjacent” refers to elements that are integral (single-piece) or in contact (not spaced or separated from) with one another. For instance, the contact pads are adjacent to the first conductive traces, but not adjacent to the second conductive traces.

The term “overlap” refers to above and extending within a periphery of an underlying element. Overlap includes extending inside and outside the periphery or residing within the periphery. For instance, in the position that the first build-up circuitry faces the upward direction, the first build-up circuitry overlaps the semiconductor device since an imaginary vertical line intersects the first build-up circuitry and the semiconductor device, regardless of whether another element such as the adhesive is between the first build-up circuitry and the semiconductor device and is intersected by the line, and regardless of whether another imaginary vertical line intersects the first build-up circuitry but not the semiconductor device (outside the periphery of the semiconductor device). Likewise, the first build-up circuitry overlaps the stiffener and the stiffener is overlapped by the first build-up circuitry. Moreover, overlap is synonymous with over and overlapped by is synonymous with under or beneath.

The term “contact” refers to direct contact. For instance, the first conductive vias contact the contact pads of the semiconductor device but the second conductive vias do not contact the contact pads of the semiconductor device.

The term “cover” refers to incomplete and complete coverage in a vertical and/or lateral direction. For instance, in the position that the first build-up circuitry faces the upward direction, the first build-up circuitry covers the semiconductor device in the upward direction regardless of whether another element such as the adhesive is between the semiconductor device and the first build-up circuitry.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening”, “aperture” and “hole” refer to a through hole and are synonymous. For instance, in the position that the stopper extends from the dielectric layer in the upward direction, the semiconductor device is exposed by the stiffener in the upward direction when it is inserted into the aperture in the stiffener.

The term “inserted” refers to relative motion between elements. For instance, the semiconductor device is inserted into the aperture regardless of whether the stiffener is stationary and the semiconductor device moves towards the stiffener, the semiconductor device is stationary and the stiffener moves towards the semiconductor device or the semiconductor device and the stiffener both approach the other. Furthermore, the semiconductor device is inserted (or extends) into the aperture regardless of whether it goes through (enters and exits) or does not go through (enters without exiting) the aperture.

The phrase “aligned with” refers to relative position between elements regardless of whether elements are spaced from or adjacent to one another or one element is inserted into and extends into the other element. For instance, the stopper is laterally aligned with the semiconductor device since an imaginary horizontal line intersects the stopper and the semiconductor device, regardless of whether another element is between the stopper and the semiconductor device and is intersected by the line, and regardless of whether another imaginary horizontal line intersects the semiconductor device but not the stopper or intersects the stopper but not the semiconductor device. Likewise, the first via opening is aligned with the contact pads of the semiconductor device, and the semiconductor device and the stopper are aligned with the aperture.

The phrase “in close proximity to” refers to a gap between elements not being wider than the maximum acceptable limit. As known in the art, when the gap between the semiconductor device and the stopper is not narrow enough, the location error of the semiconductor device due to the lateral displacement of the semiconductor device within the gap may exceed the maximum acceptable error limit. Once the location error of the semiconductor device goes beyond the maximum limit, it is impossible to align the contact pad with a laser beam, resulting in the electrical connection failure between the semiconductor device and the build-up circuitry. According to the pad size of the semiconductor device, those skilled in the art can ascertain the maximum acceptable limit for a gap between the semiconductor device and the stopper through trial and error to prevent the electrical connection failure between the semiconductor device and the build-up circuitry. Thereby, the description “the stopper is in close proximity to the peripheral edges of the semiconductor device” means that the gap between the peripheral edges of the semiconductor device and the stopper is narrow enough to prevent the location error of the semiconductor device from exceeding the maximum acceptable error limit.

The phrases “mounted on”, “mounted onto”, “attached on”, “attached onto”, “laminated on” and “laminated onto” include contact and non-contact with a single or multiple support element(s). For instance, the semiconductor device can be mounted on the shielding lid regardless of whether it contacts the shielding lid or is separated from the shielding lid by an adhesive.

The phrases “electrical connection” or “electrically connects” and “electrically connected” refer to direct and indirect electrical connection. For instance, the plated through hole provides an electrical connection for first conductive trace regardless of whether it is adjacent to the first conductive trace or electrically connected to the first conductive trace by the third conductive trace.

The term “above” refers to upward extension and includes adjacent and non-adjacent elements as well as overlapping and non-overlapping elements. For instance, in the position that the first build-up circuitry faces the downward direction, the stopper extends above, is adjacent to and protrudes from the first insulating layer.

The term “below” refers to downward extension and includes adjacent and non-adjacent elements as well as overlapping and non-overlapping elements. For instance, in the position that the first build-up circuitry faces the downward direction, the first build-up circuitry extends below the semiconductor device in the downward direction regardless of whether the first build-up circuitry is adjacent to the semiconductor device.

The “first vertical direction” and “second vertical direction” do not depend on the orientation of the wiring board, as will be readily apparent to those skilled in the art. For instance, the active surface of the semiconductor device faces the first vertical direction and the inactive surface of the semiconductor device faces the second vertical direction regardless of whether the wiring board is inverted. Likewise, the stopper is “laterally” aligned with the semiconductor device in a lateral plane regardless of whether the wiring board is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the active surface of the semiconductor device faces the downward direction, and the first vertical direction is the upward direction and the second vertical direction is the downward direction in the position that the active surface of the semiconductor device faces the upward direction.

The wiring board and the three-dimensional stacking module using the same according to the present invention have numerous advantages. For instance, the stopper can be a perfect placement guide for the semiconductor device to be shielded. As the semiconductor device is bonded to the build-up circuitry or the shielding lid by adhesive, any movement due to placement error or adhesive reflow during curing can be avoided. Therefore, the wiring board and the three-dimensional stacking module are reliable, inexpensive and well-suited for high volume manufacture. The shielding sidewalls of the stiffener and the shielding lid can respectively serve as horizontal and vertical EMI shields for semiconductor device to minimize electromagnetic interference. The signal routing provided by the build-up circuitry is advantageous for high I/O and high performance applications due to the high routing capability of the build-up circuitry. The stiffener can provide a mechanical support for the build-up circuitry and the semiconductor device packaged in the wiring board. The wiring board and the stacking module using the same are reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims. Although the present invention has been explained in relation to its preferred embodiment, it is to be understood that many other possible modifications and variations can be made without departing from the spirit and scope of the invention as hereinafter claimed.

What is claimed is:

1. A wiring board with an embedded device, a built-in stopper and electromagnetic shielding, comprising:
a semiconductor device that includes an active surface with a plurality of contact pads thereon and an inactive surface, wherein the active surface faces a first vertical direction and the inactive surface faces a second vertical direction opposite the first vertical direction;
a stopper that serves as a placement guide for the semiconductor device and is in close proximity to and laterally aligned with and laterally extends beyond peripheral edges of the semiconductor device in lateral directions orthogonal to the vertical directions;
a stiffener that includes an aperture with the semiconductor device and the stopper extending thereinto, wherein the aperture has shielding sidewalls that laterally cover peripheral edges of the semiconductor device;
a first build-up circuitry that covers the stopper, the semiconductor device and the stiffener from the first vertical direction and is electrically connected to the contact pads of the semiconductor device through first conductive vias; and
a second build-up circuitry that covers the stopper, the semiconductor device and the stiffener from the second vertical direction and includes a shielding lid that is aligned with the semiconductor device, wherein the shielding lid and the shielding sidewalls are electrically connected to at least one of the contact pads for grounding through the first build-up circuitry.

2. The wiring board of claim 1, wherein the stopper include a continuous or discontinuous strip or an array of posts.

3. The wiring board of claim 1, wherein the stopper is made of a metal or a photosensitive plastic material.

4. The wiring board of claim 1, wherein a gap in between the semiconductor device and the stopper is in a range of 0.001 to 1 mm.

5. The wiring board of claim 1, wherein the stopper has a height in a range of 10 to 200 microns.

6. The wiring board of claim 1, wherein the shielding lid is a continuous metal layer and laterally extends beyond peripheral edges of the semiconductor device outward.

7. The wiring board of claim 1, wherein the shielding sidewalls are electrically connected to the first build-up circuitry through a plated through hole that extends through the stiffener.

8. The wiring board of claim 1, wherein the shielding sidewalls are electrically connected to the first build-up circuitry through an additional first conductive via of the first build-up circuitry.

9. The wiring board of claim 1, wherein the shielding lid is electrically connected to the first build-up circuitry through a plated through hole that extends through the stiffener.

10. The wiring board of claim 1, wherein the shielding lid is electrically connected to the first build-up circuitry through the stiffener and a second conductive via of the second build-up circuitry.

11. The wiring board of claim 1, wherein the shielding lid is electrically connected to the first build-up circuitry through the stiffener and a conductive trench of the second build-up circuitry.

12. A wiring board with an embedded device, a built-in stopper and electromagnetic shielding, comprising:
a shielding lid;
a semiconductor device that is mounted on the shielding lid by an adhesive and includes an active surface with a plurality of contact pads thereon and an inactive surface opposite to the active surface, wherein the active surface faces a first vertical direction away from the shielding lid and the inactive surface faces a second vertical direction toward the shielding lid;
a stopper that serves as a placement guide for the semiconductor device and extends from the shielding lid in the first vertical direction and is in close proximity to and laterally aligned with and laterally extends beyond peripheral edges of the semiconductor device in lateral directions orthogonal to the vertical directions;
a stiffener that includes an aperture with the semiconductor device and the stopper extending thereinto, wherein the aperture has shielding sidewalls that laterally cover peripheral edges of the semiconductor device; and
a first build-up circuitry that covers the stopper, the semiconductor device and the stiffener from the first vertical direction and is electrically connected to the contact pads of the semiconductor device through first conductive vias, wherein the shielding lid and the shielding sidewalls are electrically connected to at least one of the contact pads for grounding through the first build-up circuitry.

13. The wiring board of claim 12, further comprising:
a second build-up circuitry that covers the shielding lid and the stiffener from the second vertical direction; and
a plated through hole that extends through the stiffener to provide an electrical connection between the first build-up circuitry and the second build-up circuitry.
